(19) United States
(12) Patent Application Publication
(10) Pub. No.: US 2002/0168579 A1
(43) Pub. Date: Nov. 14, 2002

(54) Image-forming material, color filter-forming material, and method of forming images and color filters

(75) Inventors: Tamotsu Suzuki, Shizuoka (JP); Naoya Imamura, Shizuoka (JP); Morimasa Sato, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/053,584

(22) Filed: Jan. 24, 2002

(30) Foreign Application Priority Data
Jan. 26, 2001 (JP) 2001-018767

(51) Int. Cl. G03F 7/34; G03C 7/06; G03C 7/12

(52) U.S. Cl. 430/7; 430/200; 430/964

(57) ABSTRACT

An image-forming material comprising: an image-receiving sheet; and a thermal transfer sheet comprising a first support, a photothermal converting layer and an image-forming layer, wherein the image-receiving sheet or each of the image-receiving sheet and the first support comprises a polyether sulfone layer comprising polyether sulfone and a method using the image-forming material.

### FIELD OF THE INVENTION

The present invention relates to an image-forming material, a color filter-forming material, a method of forming images, and a method of forming color filters. Specifically, the invention is concerned with formation of high-resolution color images and color filters by the use of laser beams in particular. Further, the invention is concerned with multicolored image formation and color filter formation useful for making color proofs or mask images in the field of graphic arts by laser recording based on digital image information (the color proofs made in such a way is called “DDCP”, or direct digital color proofs).

### BACKGROUND OF THE INVENTION

In the field of graphic arts, exposure for making a printing plate is performed using a set of color separation films formed from a color original with the aid of lith films. For checking errors in the color separation step or the necessity for color correction prior to actual printing operations, color proofs are generally made from color separation films. And the color proofs are requested to have properties of ensuring high resolution enabling high-quality reproduction of medium-tone images and high process consistency. On the other hand, as color proof materials used for obtaining color proofs closely resemble to real prints, materials used for real prints, e.g., printing paper as abase material and pigments as coloring materials, are suitable. With respect to the method of producing color proofs, dry methods using no developers are much in request.

With the recent widespread use of electronified systems in the steps prior to printing (prepress field), recording systems enabling production of color proofs directly from digital signals have been developed for color proof production in a dry process. The use of such electronified systems aims at producing color proofs of high image quality, and can generally achieve reproduction of halftone images of at least 150 lines/inch. In order to produce proofs of high image quality by recording based on digital signals, laser beams capable of being modulated by digital signals and focused to a minute cross section are applied to a recording head. Therefore, it becomes necessary to develop recording materials having high recording sensitivity to laser beams and showing high resolution to ensure reproduction of high-definition halftone dots.

As a recording material to which a transfer image formation method utilizing laser beams is applicable, there is known the thermal fusion transfer sheet having on a substrate a photothermal converting layer capable of evolving heat by absorption of laser beams and an image-forming layer comprising a pigment dispersed in a heat-fusible ingredient, such as wax or binder, in order of mention (JP-A-5-58045, the term “JP-A” as used herein means an “unexamined published Japanese patent application”). According to the image-forming method using such a recording material, the photothermal converting layer evolves heat in the laser beam-irradiated areas, and the image-forming layer is molten by the heat in the areas corresponding to the irradiated areas and transferred onto an image-receiving sheet superimposed on the transfer sheet, thereby forming transfer images on the image-receiving sheet.

Further, JP-A-6-219052 discloses the thermal transfer sheet comprising a substrate provided sequentially with a photothermal converting layer, a very thin (0.03 to 0.3 μm) heat-releasable layer and an image-forming layer containing coloring materials. In this thermal transfer sheet, the binding force between the image-forming layer and the photothermal converting layer which are bound by the mediation of the heat-releasable layer is reduced by irradiation with laser beams to result in formation of high-definition images on an image-receiving sheet superimposed on the thermal transfer sheet. The image-forming method using such a thermal transfer sheet takes advantage of the so-called ablation. More specifically, the phenomenon utilized therein is as follows. The heat-releasable layer partly decomposes and vaporizes in the areas irradiated with laser beams, and so in the areas corresponding thereto the connection force between the image-forming layer and the photothermal converting layer gets weak. As a result, the corresponding areas of the image-forming layer are transferred onto an image-receiving layer superimposed thereon.

Those image-forming methods have advantages that a printing paper to which an image-receiving layer (adhesion layer) is attached can be used as a material for image-receiving sheet and multicolored images can be obtained with ease by transferring images of different colors in succession onto an image-receiving sheet. The image-forming method utilizing ablation in particular has an advantage of easy formation of high-definition images, and is useful in producing color proofs (DDCP, or direct digital color proofs) or high-definition mast images.

On the other hand, production of color filters used for liquid crystal displays has been carried out using photosensitive transfer materials.

The principle of color filter production is based on formation of multicolored images in a photosensitive transfer material. The image formation method using such a photosensitive transfer material is explained below.

A photopolymer layer is affixed to a substrate while applying pressure and heat thereto, and therefrom a temporary support is peeled away. Then the photopolymer layer on the substrate is exposed to light via a desired mask (or a thermoplastic resin layer or an interlayer in some cases), and further subjected to development. The development can be effected by a known method comprising immersion in a solvent or an aqueous developer, especially an aqueous alkali solution, or spraying of a developer from a sprayer, and subsequent processing by a rub with a brush or irradiation with ultrasonic waves. Such a process is repeated a plural number of times by the use of photosensitive transfer materials having photopolymer layers of different colors, thereby producing multicolored images.

With recent developments in office automation, copiers and printers utilizing various recording systems, such as an electrophotographic system, an inkjet system and a heat-sensitive transfer recording system as mentioned above, have been used depending on their respective purposes. Of these recording systems, the heat-sensitive transfer recording system is being applied to color filter formation materials because it has advantages of rendering operation and maintenance easy and enabling reductions in apparatus size and cost.

On the other hand, the method of producing color filters by the use of photosensitive transfer materials has problems of rendering operations complicated, causing waste and entailing high cost because it adopts a mode of development in which a solvent is used.

However, the method of using a heat-sensitive transfer recording system of laser thermal transfer type has a problem that hitherto known image-receiving substrates undergo dimensional changes during heating and by aging upon storage because of their insufficient heat resistance to cause deterioration in the shape of transfer images and lowering of sensitivity and position accuracy.

For the purpose of shortening the recording time in the case where images are recorded with laser light, the laser light constituted of multiple beams has been used in recent years. The problem described above becomes more serious when the recording is performed using a hitherto known thermal transfer sheet and multiple beams of laser light.

### SUMMARY OF THE INVENTION

The invention aims at providing an image-forming material and a color filter-forming material which each comprise an image-receiving sheet having sufficient heat resistance and excellent dimensional stability under heating, ensuring improved shape of transfer images and enabling improvements in sensitivity and position accuracy, and further providing an image formation method and a color filter formation method using the aforesaid materials respectively.

Embodiments of the invention which can attain the aims mentioned above are described below:

(1) An image-forming material comprising an image-receiving sheet and a thermal transfer sheet having on a substrate at least a photothermal converting layer and an image-forming layer, with the image-receiving sheet alone or not only the image-receiving sheet but also the substrate comprising a polyether sulfone layer.

(2) An image-forming material as described in Embodiment (1), wherein the polyether sulfone has a glass transition temperature of 200 to 250° C.

(3) An image-forming material as described in Embodiment (1) or (2), wherein the polyether sulfone has a coefficient of linear expansion of at most 10⁻³°C.⁻¹ as determined by ASTM D-696.

(4) An image-forming material as described in any of Embodiments (1) to (3), which further has a layer functioning as a cushion between the substrate and the photothermal converting layer.

(5) An image-forming material as described in any of Embodiments (1) to (4), wherein the image-receiving sheet has on a support at least an image-receiving layer and the support is a polyether sulfone layer.

(6) An image-forming material as described in any of Embodiments (1) to (5), wherein the substrate is a substrate having undergone discharge treatment.

(7) A color filter-forming material, in which is used an image-forming material as described in any of Embodiments (1) to (6).

(8) A method of forming images, which comprises superimposing a thermal transfer sheet as described in any of Embodiments (1) to (7) upon an image-receiving sheet as described in any of Embodiments (1) to (7), and subsequently carrying out imagewise irradiation with laser light from the side of the thermal transfer sheet, thereby forming images in the image-receiving sheet.

(9) A method of forming images as described in Embodiment (8), wherein the laser light is light emitted from a semiconductor laser.

(10) A method of forming images as described in Embodiment (8) or (9), wherein the photothermal converting layer absorbs light of wavelengths in the region of 700 to 1,500 nm.

(11) A method of forming color filters, which comprises using a method of forming images as described in any of Embodiments (8) to (10).

### BRIEF DESCRIPTION OF THE DRAWINGS

FIG. 1 illustrates schematically a mechanism of multicolored image formation by laser-utilized thin film thermal transfer.

FIG. 2 is a diagrammatic drawing of an example of a configuration for the laser thermal transfer recording system usable in the invention.

FIG. 3 shows a formation example of pixels for a color filter.

The reference numerals in the figures stand for the following respectively:

1 Recording system

2 Recording head

3 Sub-scan rail

4 Recording drum

5 Thermal transfer sheets loading unit

6 Image-receiving sheet roll

7 Transfer rollers

8 Squeeze roller

9 Cutter

10 Thermal transfer sheet 10K, 10C, 10M and 10Y Thermal transfer sheet rolls

12 Substrate

14 Photothermal converting layer

16 Image-forming layer

20 Image-receiving sheet

22 Support for image-receiving sheet

24 Image-receiving layer

30 Lamination

31 Ejection stage

32 Waste exit

33 Ejection mouth

34 Air

35 Waste box

41 Color filter

42 Red filter pixel

43 Green filter pixel

44 Blue filter pixel

45 Black matrix

### DETAILED DESCRIPTION OF THE INVENTION

Image-forming materials and color filter-forming materials according to the invention are each constituted of an image-receiving sheet and a thermal transfer sheet having on a substrate at least a photothermal converting layer and an image-forming layer. These materials are each characterized in that the image-receiving sheet alone or not only the image-receiving sheet but also the substrate of the thermal transfer sheet comprises a polyether sulfone layer. In the invention, the substrate of the thermal transfer sheet may be formed of a polyether sulfone layer alone.

The image-receiving sheet may also be formed of a polyether sulfone layer alone, but it is preferable for the sheet to have a structure that at least an image-receiving layer is provided on a polyether sulfone layer as a support. In the case of using the polyether sulfone layer as the image-receiving sheet of a color filter, on the other hand, it is appropriate that the sheet be constituted of polyether sulfone alone. However, known additives, such as a matting agent, reinforcing fibers and other polymers, maybe added to the polyether sulfone layer.

The polyether sulfone is an amorphous polymer synthesized by polycondensation of dichlorodiphenylsulfone and a bisphenol compound and having a structure represented by the following formula (I). In the invention, polyether sulfone having not only a desired molecular weight but also desired physical properties can be selected by appropriately controlling the value of an integer “n”.

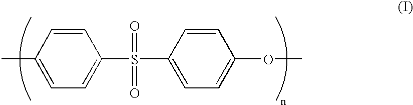

In the invention, it is appropriate for the polyether sulfone to have a glass transition temperature in the range of 200 to 250° C, preferably 220 to 250° C., and a coefficient of linear expansion of at most 10⁻³° C.⁻¹, preferably at most 10⁻⁴°C.⁻¹, as determined by ASTM D-696.

The polyether sulfone having such physical properties can be selected appropriately from those described in, e.g., a book entitled “Electronics yo Jushi” (which may be translated “Resins for Electronics”), pp. 197-201, published by Toray Research Center (Sep. 1, 1999), and a book entitled “Kobunshi Shin-Sozai Binran” (which may be translated “Handbook of New Polymeric Materials”), pp.542-546, compiled by Polymeric Society, published by Maruzen (Sep. 20, 1989). Examples of polyether sulfone suitably used in the invention include Sumilite FS-1300 produced by Sumitomo Bakelite Co., Ltd., and E1010, E2010 and E3010 produced by Mitsui Chemical Co., Ltd.

In the era of CTP (Computer To Plate), films are unnecessary, but contract proofs taking the place of proofs or color arts are necessary. In order to obtain customers' approval, reproduction of colors matching those of prints or color arts is required of the contract proofs. Therefore, the present applicant has developed a digital direct color proof system (abbreviated as “DDCP system”) using the same pigment-type coloring materials as used in printing ink, enabling transfer to printing paper and causing no moire. The aim in this development is to provide a large-sized (A2-size/B2-size) DDCP system which uses the same pigment-type coloring materials as printing ink, enables transfer to printing paper and ensures close resemblance to prints. The present invention is suitable for a method of enabling transfer to printing paper by using a laser thin film thermal transfer system and pigment-type coloring materials and performing actual halftone recording. Further, this DDCP system is applied appropriately to formation of color filters.

The invention is effective and appropriate for systems which ensure thermal transfer images made up of sharp halftone dots and enable transfer to printing paper and large-size recording (measuring 515 mm by 728 mm; incidentally B2-size measures 543 mm by 765 mm).

Those transfer images can be made halftone images responsive to the number of printed lines at 2400-2540 dpi resolution. Each of the dots is almost free of bleeding and nicks, or very sharp in shape, and so halftone dots can be clearly formed over a wide range of high lights to shadows. As a result, high-definition halftone output becomes feasible at the same resolution as an image setter or a CTP setter has, and halftone dots and gradation closely analogous to prints can be reproduced. Further, it becomes possible to form s color filter by those halftone dots being made to correspond with pixels of a color filter, e.g., red (R), green (G), blue (B) and black (K) (matrix) constituent elements.

Furthermore, as these thermal transfer images are sharp in dot shape, they can faithfully reproduce not only dots corresponding with laser beams but also pixels. In addition, their recording characteristics depend slightly on environmental temperature and humidity, so their hues and intensities can be consistently reproduced many times under circumstances in wide temperature and humidity ranges.

Since the transfer images are formed with coloring pigments used for printing ink and can be reproduced with satisfactory repeatability, they permit a color management system (CMS) of high accuracy to be achieved.

In addition, the hues of the thermal transfer images can be adjusted so as to almost match the hues of Japan colors or SWOP colors, namely hues of prints. Therefore, although the colors of the transfer images vary their appearances when they are viewed under different light sources, such as a fluorescent lamp and an incandescent lamp, such variations in appearances can be made the same as those caused in colors of prints.

Moreover, the thermal transfer images are sharp in dot shape, so they can reproduce crisply minute letters or a black matrix, and pixels. The heat produced by laser light is transmitted to a transfer surface without diffusing in horizontal directions, and the image-forming layer ruptures sharply at the interface between the heated and unheated areas. In order to achieve such a sharp rupture, reduction in thickness of a photothermal converting layer in the thermal transfer sheet and control of physical characteristics of the image-forming layer are made.

Incidentally, according to estimates by simulation, the photothermal converting layer reaches a temperature of about 700° C. momentarily. Therefore, when such a layer has a reduced thickness, it is liable to be deformed or broken. If once the photothermal converting layer is deformed or broken, it causes actual harms of being transferred to an image-receiving sheet together with the transfer layer and rendering the transfer images nonuniform. For attaining the desired temperature, on the other hand, it is necessary to incorporate a high concentration of light-to-heat converting ingredient in the layer. As a result, problems that dyes separate out or pass into the adjacent layers are caused.

Accordingly, it is appropriate for the photothermal converting layer to selectively use infrared absorbing dyes having excellent light-to-heat conversion characteristics and a heat-resistant binder such as polyimide and to have a thickness reduced to about 0.5 μm or below.

When the photothermal converting layer becomes deformed or the image-forming layer itself is deformed by high heat, the image-forming layer transferred to an image-receiving layer generally suffers from unevenness in thickness according to a sub-scan pattern of laser light, and thereby the images obtained become nonuniform and the apparent transfer density is lowered. This tendency becomes more pronounced the thinner thickness the image-forming layer has. On the other hand, an increase in thickness of the image-forming layer causes a loss of dot sharpness and reduction in sensitivity.

For attaining these properties which are mutually contradictory, it is favorable to improve evenness in transfer by the addition of a low melting point substance, such as wax, t6o the image-forming layer. Further, proper increase in thickness of the image-forming layer by adding inorganic fine particles instead of a binder permits a sharp rupture of the image-forming layer at the interface between heated and unheated areas, and thereby the unevenness in transfer can be reduced as the sharpness of dots and the sensitivity are retained.

In general, low melting point substances, such as waxes, have a tendency to exude to the surface of the image-forming layer or crystallize. In some cases, therefore, they cause degradations in image quality and storage stability of the thermal transfer sheet.

For dealing with this problem, it is favorable to use a low melting point substance slightly different in Sp value from a polymer constituting the image-forming layer. Such a low melting point substance has high compatibility with the polymer and can avoid separation from the image-forming layer. And it is also favorable to prepare an eutectic mixture by the use of several kinds of low melting point substances having different structures, thereby preventing them from crystallizing. As a result, images having a sharp dot shape and reduced unevenness can be obtained.

In general, coating layers of a thermal transfer sheet change their mechanical and thermal properties by absorption of moisture, which creates a dependence on the humidity of a recording environment.

For reduction of the aforesaid dependence on temperature and humidity, it is appropriate that the dye and binder components in the photothermal converting layer and the binder component in the image-forming layer be made into organic solvent-based compositions. Further, there is known a method of selecting polyvinyl butyral as the binder of the image-receiving layer and introducing an art of rendering polymers hydrophobic to reduce water absorbency. Examples of such an art include the art of reacting hydroxyl groups with hydrophobic groups and the art of cross-linking two or more hydroxyl groups with a curing agent, as disclosed in JP-A-8-238858.

In printing by exposure to laser light, heat of no lower than about 500° C. is generally applied to the image-forming layer also, and this heat decomposes some of hitherto used pigments. However, such thermal decomposition of pigments can be prevented by adoption of highly heat-resistant pigments in the image-forming layer.

Further, the high heat evolved upon printing causes migration of infrared absorbing dyes from the photothermal converting layer to the image-forming layer and brings about a change in hue. In order to prevent the change in hue, it is favorable to design the photothermal converting layer so as to contain infrared absorbing dyes in concert with binders having strong holding power.

In general, high-speed printing causes an energy shortage, and thereby gaps corresponding to intervals between sub-scans of laser in particular are formed. As mentioned above, the efficiencies of generation and transfer of heat can be improved by increasing a dye concentration in the photothermal converting layer and reducing thicknesses of the light-to-heat converting and the image-forming layers. For the purposes of filling in the gaps by slight fluidization of the image-forming layer under heating and enhancing adherence to an image-receiving layer, it is appropriate that a low melting point substance be added to the image-forming layer. Further, the same binder as used in the image-forming layer, namely polyvinyl butyral, can be adopted as the binder of the image-receiving layer with the intentions of enhancing an adhesion force between the image-receiving layer and the image-forming layer and ensuring sufficient strength in the transferred images.

It is appropriate for the image-receiving sheet and the thermal transfer sheet to be held on a drum by vacuum contact. It is important to carry out vacuum contact because images are formed through control of an adhesion force between both sheets and the image transfer behavior is very sensitive to clearance between the image-receiving layer surface of the image-receiving sheet and the image-forming layer surface of the transfer sheet. When an alien substance such as dust adheres to the layer surfaces, clearance between the sheets is widened to result in occurrence of imperfections in images and uneven transfer of images.

In order to prevent occurrence of image imperfections and uneven transfer of images, it is advantageous to provide uniform asperity on the surface of the thermal transfer sheet to improve air passage, thereby securing uniform clearance.

As methods for providing asperity on the surface of a thermal transfer sheet, an after-treatment, such as embossing, and addition of a matting agent to a coating layer are generally known. From the viewpoints of simplicity of the manufacturing process and storage stability of the material, the addition of a matting agent is preferred. The matting agent is required to have a particle size greater than the coating layer thickness, but the matting agent added to the image-forming layer has a drawback of causing image dropouts in the spots where the matting agent particles are present. Therefore, it is preferable to add a matting agent having the most suitable particle size to the photothermal converting layer. And by doing so, the image-forming layer itself can have an almost uniform thickness and defects-free images can be obtained on the image-receiving sheet.

In order to reproduce sharp dots with reliability, as described hereinbefore, a high-precision design is required on the part of the recording system also. The basic configuration of a recording system usable in the invention is the same as that of a traditional recording system for laser thermal transfer. Specifically, the recording system used in the invention can be basically configured as the so-called outer drum recording system in heat mode, or the system of recording by irradiating thermal transfer and image-receiving sheets fixed on a drum with laser beams emitted from a recording head provided with a plurality of high-power laser devices. The following is a suitable embodiment of such a configuration.

Image-receiving sheets and thermal transfer sheets are fed by full automatic roll feeding. The sheets fed automatically are fixed to a recording drum by vacuum adsorption. The recording drum is designed so as to have many holes at the surface for vacuum adsorption and the interior of the drum is decompressed with a blower or a pressure-reducing pump. As a result, the sheets are stuck on the recording drum. The image-receiving sheet is adsorbed to the recording drum first, and then the thermal transfer sheet is adsorbed to the image-receiving sheet on the recording drum. Therefore, the size of the thermal transfer sheet is made greater than that of the image-receiving sheet. The air present in a clearance between the thermal transfer sheet and the image-receiving sheet, which has great influences on the recording performance, is sucked from the area of the thermal transfer sheet that extends off the image-receiving sheet.

The recording system used in the invention is designed so that a great many sheets of large dimensions, such as B2-size, are stacked on an ejection stage. Therefore, the system adopts a method of sending an air blast between two sheets, and thereby floating the sheet to be discharged later.

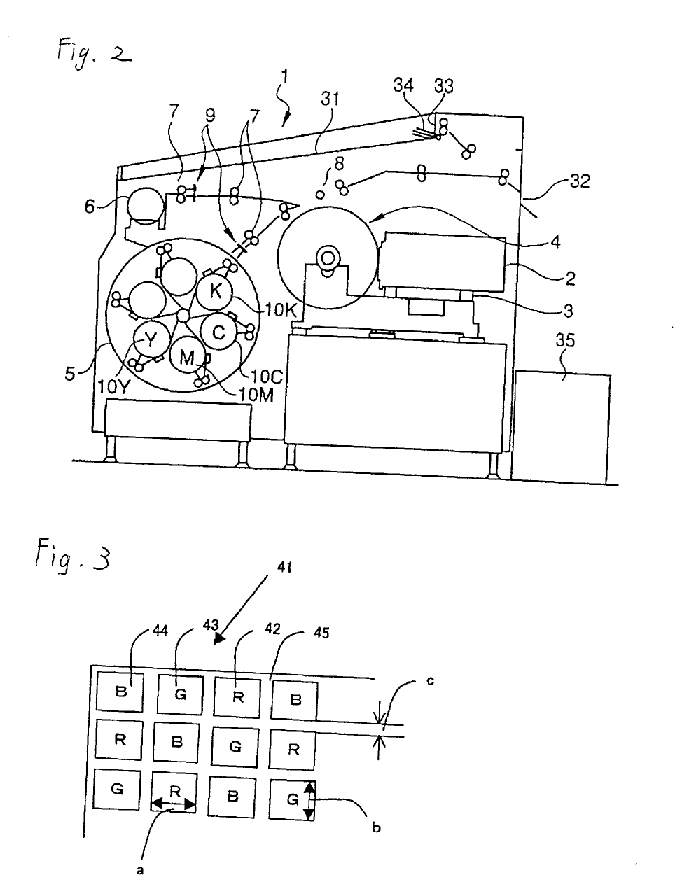

An example of a configuration adopted by the present recording system is shown in FIG. 2.

The sequence performed in the present recording system as mentioned above is explained below.

1) In the recording system 1, the sub-scan axis of the recording head 2 is returned to its original position by means of the sub-scan rail 3, and the main-scan rotation axis of the recording drum 4 and the thermal transfer sheet loading unit 5 are also returned to their respective original positions.

2) The image-receiving sheet roll 6 is unrolled by means of the transfer rollers 7, and the leading end of the image-receiving sheet is fixed on the recording drum 4 by vacuum suction via suction holes made in the recording drum 4.

3) The squeeze roll 8 is brought down to the recording drum 4 and presses the image-receiving sheet against the recording drum, and while being pressed against the drum the image-receiving sheet is further conveyed in a specified quantity by rotation of the drum. At this point, the conveyance of the image-receiving sheet is brought to a halt and the image-receiving sheet is cut to a specified length.

4) The loading of the image-receiving sheet is completed by further rotating the recording drum one turn.

5) Next, the thermal transfer sheet K of the first color, namely black, is unreeled from the thermal transfer sheet roll 10K, cut and loaded according to the same sequence as the image-receiving sheet has followed.

6) Then, the recording drum 4 commences rotating at a high speed, and at the same time the recording head 2 on the sub-scan rail 3 commences moving. When the recording head 2 reaches the recording start position, the laser radiation based on recording image signals is applied to the recording drum 4 from the recording head 2. The irradiation with laser is terminated at the recording end point, and the movement on the sub-scan rail and the rotation of the drum are brought to a stop. Further, the recording head on the sub-scan rail is returned to its original position.

7) Only the thermal transfer sheet K is peeled away as the image-receiving sheet is left on the recording drum. Therein, the front end of the thermal transfer sheet K is hooked on a nail and pulled out in the direction of ejection, followed by throwing it away from the waste exit 32 in the waste box 35.

8) The operations in the processes 5) to 7) are repeated for each of the remaining three colors of thermal transfer sheets The recording order, from the first to the last, is black, cyan, magenta and yellow. Specifically, it is carried out sequentially to unreel the thermal transfer sheet C of the second color, namely cyan, from the thermal transfer sheet roll 10C., the thermal transfer sheet M of the third color, namely magenta, from the thermal transfer sheet roll 10M and the thermal transfer sheet Y of the fourth color, namely yellow, from the thermal transfer sheet roll 10Y. This order is opposite to the general printing order. This is because the order of colors is reversed on printing paper in the later processes of transferring color images to the printing paper.

9) After the recording in four colors is completed, the image-recorded image-receiving sheet is ejected until it reaches the ejection stage 31. The image-receiving sheet is peeled away from the drum in the same manner as the thermal transfer sheets are peeled away in the process 7). However, the image-receiving sheet is not scraped in contrast to the thermal transfer sheets. Therefore, the image-receiving sheet having traveled to the waste exit 32 is turned back toward the ejection stage by switchback. The ejection to the ejection stage is performed by blowing the air 34 from the underside of the ejection mouth 33, and this air blow permits stacking of a plurality of image-receiving sheets.

It is advantageous that tacky rolls on the surface of which a tacky substance is provided are adopted as transfer rollers 7 present in either feed sections or transfer sections of the thermal transfer sheet rolls and the image-receiving sheet roll.

By installing tacky rolls, it becomes possible to clean the surfaces of thermal transfer and image-receiving sheets.

Examples of a tacky substance provided on the surfaces of tacky rolls include ethylene-vinyl acetate copolymer, ethylene-ethyl acrylate copolymer, polyolefin resin, polybutadiene resin, styrene-butadiene copolymer (SBR), styrene-ethylene-butene-styrene resin (SEBS), acrylonitrile-butadiene copolymer (NBR), polyisoprene resin (IR), styrene-isoprene copolymer (SIS), acrylate copolymers, polyester resins, polyurethane resin, acrylic resins, butyl rubber and polynorbornene.

The surfaces of thermal transfer and image-receiving sheets can be cleaned merely by contact with tacky rolls. There is no particular limits to the contact pressure in this case so long as the roll surface is in contact with the sheet surface.

The suitable difference in surface roughness Rz between the image-forming layer surface and the backing layer surface of the thermal transfer sheet is at most 3.0 in absolute-value terms, and that between the image-receiving layer surface and the backing layer surface of the image-receiving sheet is also at most 3.0 in absolute-value terms. By designing the sheet surfaces so as to have such roughness in addition to the use of the foregoing cleaning means, occurrence of image imperfections can be prevented, a transfer jam can be avoided, and dot grain consistency can be enhanced.

The term “surface roughness Rz” as used herein refers to the ten-point average surface roughness corresponding to Rz (maximum height) of JIS. More specifically, the average surface of a section having a standard area drawn from a rough surface is adopted as a datum surface. From the highest to the fifth highest peaks and from the deepest to the fifth deepest valleys present at the datum surface are picked out, and the mean height of those five peaks and the mean depth of those five valleys are determined. The thus determined mean distance between the peak top and the valley bottom is defined as surface roughness Rz. The determination of Rz value can be made by using a three-dimensional roughness tester adopting a stylus method, e.g., Surfcom 570 A-3DF, made by Tokyo Seimitu K.K. The measurement conditions adopted therein are, e.g., as follows: The measurement is carried out in the vertical direction, the cut-off value is 0.08 mm, the measurement area is 0.6 mm by 0.4 mm, the feed pitch (scanning interval) is 0.005 mm, and the measurement speed is 0.12 mm/s.

From the viewpoint of further enhancing the foregoing effects, it is advantageous that the difference in surface roughness Rz between the image-forming layer surface and the backing layer surface of the thermal transfer sheet is at most 1.0 in terms of absolute value and that between the image-receiving layer surface and the backing layer surface of the image-receiving sheet is also at most 1.0 in terms of absolute value.

In another embodiment, it is appropriate that the surface roughness Rz values of the image-forming and backing layers of the thermal transfer sheet and/or those of the front and rear surfaces of the image-receiving sheet be from 2 to 30 μm. By designing the thermal transfer sheet and the image-receiving sheet so as to have such roughness values in addition to the use of the cleaning means mentioned hereinbefore, occurrence of image imperfections can be prevented, a transfer jam can be avoided, and dot grain consistency can be enhanced.

Further, it is advantageous that the image-forming layer of the thermal transfer sheet has a glossiness of 80 to 99.

The glossiness depends to a large degree on the smoothness of the image-forming layer surface, and thereby the uniformity of the image-forming layer thickness can be influenced. The image-forming layer is more uniform and more suitable for high-definition image formation the higher glossiness it has. However, the higher glossiness of the image-receiving layer causes the stronger resistance in the process of transfer. In other words, there is a trade-off relation between higher glossiness and lower transfer resistance. As far as the glossiness is in the range of 80 to 99, those two factors can go hand in hand, and the balance between them is achieved.

For the tacky material used for tacky rolls, it is appropriate to have a Vickers hardness Hv of at most 50 kg/mm² (roughly corresponding to 490 MPa) from the viewpoints of a total elimination of foreign particles such as dust and prevention of image imperfections.

The Vickers hardness Hv is a hardness measured with a static load-imposed diamond stylus in the shape of a right pyramid having a facing angle of 136°, and defined by the following equation:

Hv=1.854P/d² (kg/mm²)≈28.2692 MPa

wherein P is a value of the load imposed (kg) and d is a diagonal length of the indentation in square shape (mm).

In addition, it is appropriate for the tacky material used for tacky rolls to have an elasticity modulus of at most 200 kg/cm² (≈19.6 MPa) at 20° C. from the viewpoints of complete removal of dust as a foreign matter and reduction of image imperfections.

The above illustration of the present recording system is made centering on the outer drum mode. Also, it is possible to adopt an inner drum mode or a flat bed mode.

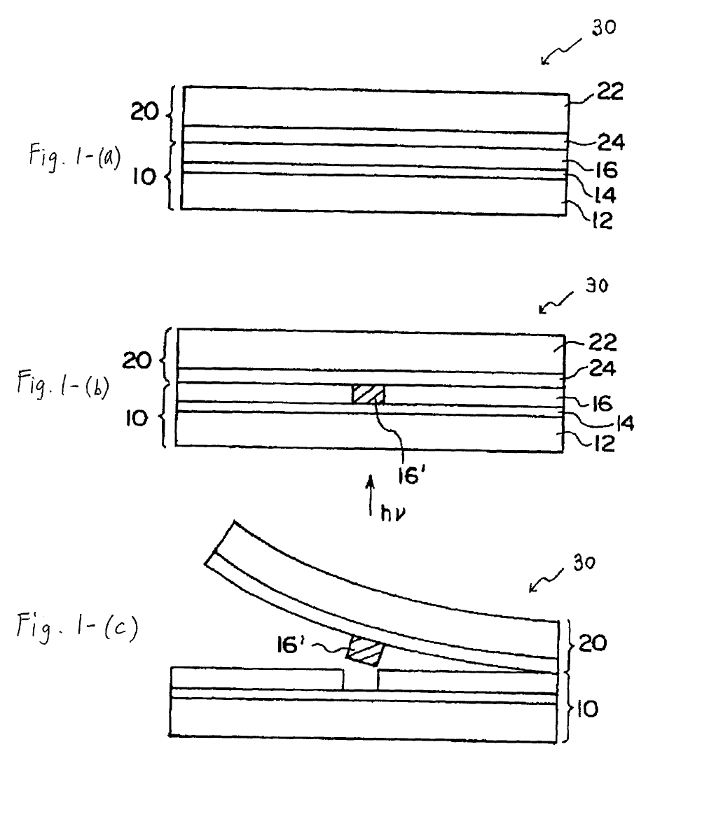

Next the mechanism of multicolored image formation by laser-utilized thin-film thermal transfer is schematically illustrated with the aid of FIG. 1.

A laminate 30 for image formation is prepared by laminating an image-receiving sheet 20 on the surface of a black (K), cyan (C), magenta (M) or yellow (Y) pigment-containing image-forming layer 16 of a thermal transfer sheet 10. The thermal transfer sheet 10 has a substrate 12, a photothermal converting layer 14 provided on the substrate, and further an image-forming layer 16 on the converting layer 14. The image-receiving sheet 20 has a support 22 and an image-receiving layer 24 on the support, and is laminated on the thermal transfer sheet 10 so that the image-receiving layer 24 is brought into contact with the surface of the image-forming layer 16 (FIG. 1 (a)) . The laminate 30 undergoes imagewise irradiation with laser light in time sequence from the side of the substrate 12 of the thermal transfer sheet 10. Thereby, the photothermal converting layer 14 of the thermal transfer sheet 10 produces heat in the laser light-irradiated area. As a result, the adhesion of the photothermal converting layer 14 to the image-forming layer 16 is lowered in the area having produced heat (FIG. 1(b)). Thereafter, the image-receiving sheet 20 is peeled away from the thermal transfer sheet 10 to result in transfer of the laser light-irradiated area 16′ of the image-forming layer 16 to the image-receiving layer 24 of the image-receiving sheet 20 (FIG. 1 (c) ) .

In the case of forming pixels of a color filter on the image-receiving layer, thermal transfer sheets 10 having image-forming layers containing, e.g., red, green and blue pigments are used in place of the thermal transfer sheets containing cyan (C), magenta (M) and yellow (Y) pigments in their respective image-forming layers 16, and the black (K) thermal transfer sheet is used for black matrix.

In the multicolored image formation, laser light suitable for irradiation is multiple-beam light, especially two-dimensional array of multiple beams. The term “two-dimensional array of multiple beams” as used herein means that a plurality of laser beams are used in recording by irradiation with laser light and a spot array of these laser beams takes the form of a two-dimensional flat matrix composed of a plurality of columns along the direction of the main-scan direction and a plurality of rows along the direction of the sub-scan direction.

By using laser light composed of a two-dimensional array of multiple beams, the time required for laser recording can be cut off.

The laser light usable in the invention has no particular restrictions so long as it is multiple-beam laser. Specifically, it includes direct laser light such as gas laser light (e.g., argon-neon laser light, helium-neon laser light or helium-cadmium laser light), solid laser light (e.g., YAG laser light), semiconductor laser light, dye laser light and excimer laser light. In addition, the light obtained by passing laser light as recited above through a second harmonic device to reduce its wavelength to the half can also be used. Informing multicolored images, it is advantageous to use semiconductor laser light from the viewpoints of power of output and easiness of modulation. For multicolored image formation, it is appropriate to perform irradiation under a condition that the beam diameter of laser light on the photothermal converting layer be in the range of 5 to 50 μm (particularly 6 to 30 μm) and the scanning speed be adjusted to at least 1 m/sec (preferably at least 3 m/sec).

Furthermore, it is appropriate for multicolored image formation that the thickness of the image-forming layer in a black thermal transfer sheet be greater than those in thermal transfer sheets of other colors, and that in the range of 0.5 to 2.5 μm, preferably 0.5 to 0.7 μm. By such thickness adjustment, it is possible to control the lowering of image density due to uneven transfer when the black thermal transfer sheet is irradiated with laser.

When the image-forming layer of the black transfer sheet has a thickness smaller than 0.5 μm, nonuniform transfer occurs in the case of high-energy recording. As a result, a substantial reduction of the image density is caused, and it tends to become difficult to attain the image density required for proofs. Such a tendency is remarkable under high humidity conditions, so that a great change in density may occur depending on environments. On the other hand, the image-forming layer thickness greater than 2.5 μm causes a reduction in transfer sensitivity when recording is performed with laser light. As a result, adhesion of small dots tends to deteriorate, or thinning of fine lines tend to occur. Such a tendency is more noticeable under lower humidity conditions. Further, resolution may be lowered. The more suitable thickness of the image-forming layer in the black thermal transfer sheet is from 0.55 to 0.65 μm, especially 0.60 μm.

Furthermore, it is appropriate that the thickness of the image-forming layer in the black thermal transfer sheet be from 0.5 to 0.7 μm and those in yellow, magenta and cyan thermal transfer sheets or those in red, green and blue thermal transfer sheets be each from 0.2 to thinner than 0.5 μm.

When the image-forming layer in the thermal transfer sheet of each color has a thickness smaller than 0.2 μm, density reduction due to nonuniform transfer may occur in the case of laser recording; while, when the thickness is 0.5 μm or greater, lowering of transfer sensitivity or deterioration of resolution may be caused. The more suitable thickness of those image-forming layers each is in the range of 0.3 to 0.45 μm.

It is advantageous that the black thermal transfer sheet contains carbon black in its image-forming layer. And the carbon black is preferably a carbon black mixture of at least two kinds differing in staining power. This is because the use of such a mixture enables the control of reflection density while maintaining the P/B (pigment/binder) ratio within a specified range.

The staining power of carbon black can be represented in various ways. For instance, it can be expressed in terms of PVC blackness as described in JP-A-10-140033. The term “PVC blackness” signifies the value evaluated as follows: A sample is prepared by adding a carbon black specimen to PVC resin, dispersing the carbon black into the resin and then forming the carbon black-dispersed resin into a sheet. The carbon black products marketed under the trade names of Carbon Black #40 and #45 by Mitsubishi Chemical Corporation are adopted as standard specimens, and the blackness values of the sheets prepared using those products in the manner mentioned above are graded as point 1 and point 10 respectively. By the use of these values as the standards of reference, the blackness of the sample is evaluated visually. And it is feasible to properly select two or more carbon black products differing in PVC blackness depending on the required purpose and use them.

Multicolored image formation may be carried out by, as mentioned above, using many thermal transfer sheets differing in color and superimposing on the same image-receiving sheet the image-forming layer (wherein images have been formed) of each of those thermal transfer sheets in sequence, or by once forming an image of each color on the image-receiving layer of each of many image-receiving sheets and then retransferring these images of different colors to a printing paper.

In the latter case, for instance, thermal transfer sheets whose image-forming layers contain colorants differing in hue respectively are prepared, and formed independently into image-forming laminates of 4 types (4 colors, namely cyan, magenta, yellow and black) by being combined with image-receiving sheets. Each of the laminates is irradiated with laser light according to digital signals based on images via a color separation filter, and subsequently the thermal transfer sheet is peeled away from the image-receiving sheet. Thus, color separation images of each color are formed independently on each image-receiving sheet. Then, the color separation images formed are laminated in sequence on an actual support prepared separately, such as a printing paper, or a support similar thereto. In the manner as mentioned above, multicolored images can be formed.

In the case of forming a color filter as multicolored images as mentioned above, a black matrix and pixels can be formed on an image-receiving sheet by using black, red, green and blue thermal transfer sheets in the same manner as described above. Further, a transparent protective layer maybe provided on the color filter formed. Additionally, the black, red, green and blue images may be transferred in an arbitrary order.

In thermal transfer recording by irradiation with laser light, the state in which the pigment, dye or image-forming layer is at the time when it undergoes transfer becomes no particular problem so long as the image-forming layer containing a pigment can be transferred to an image-receiving sheet by utilization of thermal energy converted from laser beams, but it includes a solid state, a softened state, a liquid state and a gas state. Of these states, solid and softened states are preferred over the others. In the suitable types of thermal transfer recording by irradiation with laser light, hitherto known transfer of fusion type, transfer by ablation and transfer of sublimation type are included.

Of these types, the transfer of the foregoing thin-film, fusion and ablation types are advantageous over the others from the viewpoint of enabling image formation having hues similar to those obtained in graphic arts.

In general, the process of transferring images printed in an image-receiving sheet by means of a recording device to printing paper is effected by the use of a thermal laminator. When heat and pressure are applied to the image-receiving sheet on which printing paper is superimposed, the image-receiving sheet is bonded to the printing paper. Then, the image-receiving sheet is peeled away from the printing paper and thereby image-carrying image-receiving layer alone is left on the printing paper.

By connecting the foregoing devices up to a plate-making system, a system capable of performing a function as color proof can be constructed. It is required for the system that print output of image quality closely akin to that of prints produced from plate-making data be produced from the recording device. Therein, software for bringing colors and dots close to those of the prints becomes a necessity. An example of connection is illustrated below.

In taking color proofs of prints from a plate-making system (e.g., Celebra made by Fuji Photo Film Co., Ltd.), the connection in the system is carried out as follows. A CTP (Computer-to-Plate) system is connected to a plate-making system. The printing plate produced as output from the plate-making system is mounted in a printing machine, and undergoes printing operations to provide final prints. In connecting the recording system as color proof to the plate-making system, a PD (trade name) system as a proof drive software is connected between those two systems for the purpose of bringing colors and dots close to those of prints.

Continuous tone data converted to raster data by the plate-making system are converted to binary data for halftone dots, output to the CTP system, and finally printed. On the other hand, the same continuous tone data are output to the PD system also. The PD system converts the data received therein so as to match up with colors of the prints by means of a four-dimensional (black, cyan, magenta and yellow) table. Finally, the resulting data are converted to binary data for halftone dots so as to match with the halftone dots of the prints, and output to the recording system.

The four-dimensional table is made empirically in advance, and stored in the system. Experiments for table formation are as follows. Images printed from important color data via a CTP system and image output produced by the recording system via the PD system are prepared, and examined for their colors with a calorimeter. A comparison between the calorimetric values of those images with respect to each color is performed, and the table is made so as to minimize differences between those calorimetric values.

In forming a color filter by application of the foregoing system, a print is replaced by pixel images or a black matrix image of the color filter and, at the same time, cyan, magenta and yellow colors are replaced by red, green and blue colors in the PD system. As an arrangement of the pixels and black matrix in the color filter, the arrangement shown in FIG. 3 can be exemplified. However, the invention should not be construed as being limited to such an arrangement. Additionally, when the sizes of a red filter pixel (R), green filter pixel (G) and blue filter pixel (B) are each expressed in terms of axb as in FIG. 3, a is from 100 to 300 μm and b is of the order of 300 μm. And the line width of the black matrix denoted by c in FIG. 3 is from 10 to 20 μm. However, these values may be changed as appropriate.

Thermal transfer sheets and image-receiving sheets suitably used in the aforementioned recording system are illustrated below.

[Thermal Transfer Sheet]

The thermal transfer sheet has on a substrate at least a photothermal converting layer and an image-forming layer, and further may have other layers, if desired.

(Substrate)

The substrate for the thermal transfer sheet is not particularly restricted as to its material, but various substrate materials can be used depending on the intended purposes. Suitable substrates are those having stiffness, good dimensional stability and heat resistance high enough to withstand the heat produced by image formation. Suitable examples of a substrate material include synthetic resin materials, such as polyethylene terephthalate, polyethylene-2,6-naphthalate, polycarbonate, polymethyl methacrylate, polyethylene, polypropylene, polyvinyl chloride, polyvinylidene chloride, polystyrene, styrene-acrylonitrile copolymer, polyamide (aromatic or aliphatic), polyimide, polyamideimide, polysulfone and polyether sulfone. Of these synthetic resins, biaxially stretched polyethylene terephthalate and polyether sulfone are preferred over the others from the viewpoints of mechanical strength and thermal dimensional stability. When the thermal transfer sheet is applied to formation of a colorproof by the use of laser recording, it is appropriate that the substrate of the thermal transfer sheet be made from a transparent synthetic resin material capable of transmitting laser light. The suitable thickness of a substrate is from 25 to 130 μm, particularly preferably from 50 to 120 μm. The suitable center-line average surface roughness Ra (determined with a roughness tester, e.g., Surfcom made by Tokyo Seiki Co., Ltd., according to JIS B60601) the substrate has on the image-forming layer side is below 0.1 μm. The suitable Young's modulus of the substrate in the length direction is from 200 to 1,200 Kg/mm² (≈2 to 12 GPa), and the suitable Young's modulus of the substrate in the width direction is from 250 to 1,600 Kg/mm² (≈2.5 to 16 GPa). The suitable F-5 value of the substrate in the length direction is from 5 to 50 Kg/mm² (≈49 to 490 MPa), and the suitable F-5 value of the substrate in the width direction is from 3 to 30 Kg/mm² (≈29.4 to 294 MPa) . The F-5 value of the substrate in the length direction is generally greater than that in the width direction, but it goes without saying that such a restriction can be removed when high strength is required in the width direction in particular. The suitable thermal shrinkage ratios of the substrate in the length and width directions under heating at 100° C. for 30 minutes are each at most 3%, preferably at most 1.5%, and those under heating at 80° C. for 30 minutes are each at most 1%, preferably at most 0.5%. The suitable tensile strength of the substrate at break in both directions is from 5 to 100 Kg/mm² (≈49 to 980 MPa), and the suitable elasticity modulus of the substrate is from 100 to 2,000 Kg/mm2 (≈0.98 to 19.6 GPa).

The substrate of the thermal transfer sheet may be subjected to a surface activation treatment and/or provided with one or more than one subbing layer for the purpose of improving adherence to a photothermal converting layer to be provided thereon. As examples of such a surface activation treatment, mention may be made of glow discharge treatment and corona discharge treatment. Materials suitable for the subbing layer are those having high adherence to both the substrate and the photothermal converting layer, low thermal conductivity and high heat resistance are suitable. Examples of such materials include styrene, styrene-butadiene copolymer and gelatin. The total thickness of subbing layers is generally from 0.01 to 2 μm. On the side opposite to the side where a photothermal converting layer is provided, the thermal transfer sheet can be provided with various functional layers, such as an antireflective layer and an antistatic layer, or subjected to surface treatment, if desired.

(Backing Layer)

The thermal transfer sheet can be provided with a backing layer on the side opposite to the side where a photothermal converting layer and an image-forming layer are provided. Examples of an antistatic agent which can be used in the backing layer include nonionic surfactants such as polyoxyethylenealkylamines and glycerol fatty acid esters, cationic surfactants such as quaternary ammonium salts, anionic surfactants such as alkyl phosphates, amphoteric surfactants and conductive compounds such as conductive resins.

In addition, conductive fine grains can also be used as antistatic agent. Examples of fine grains usable as antistatic agent include oxides such as ZnO, TiO₂, SnO₂, Al₂O₃, In₂O₃, MgO, BaO, CoO, CuO, Cu₂O, CaO, SrO, BaO₂, PbO, PbO₂, MnO₃, MoO₃, SiO₂, ZrO₂, Ag₂O, Y₂O₃, Bi₂O₃, Ti₂O₃, Sb₂O₃, Sb₂O₅, K₂Ti₆O₁₃, NaCaP₂O₁₈ and MgB₂O₅, sulfides such as CuS and ZnS, carbides such as SiC, TiC, ZrC, VC, NbC, MoC and WC, nitrides such as Si₃N₄, TiN, ZrN, VN, NbN and Cr₂N, borides such as TiB₂, ZrB₂, NbB₂, TaB₂, CrB, MoB, WB and LaB₅, silicides such as TiSi₂, ZrSi₂, NbSi₂, TaSi₂, CrSi₂, MoSi₂ and WSi₂, metal salts such as BaCO₃, CaCO₃, SrCO₃, BaSO₄ and CaSO₄, and complexes such as SiN₄-SiC and 9Al₂O₃-2B₂O₃. These compounds may be used alone or as varying combinations of them. Of those compounds, SnO₂, ZnO, Al₂O₃, TiO₂, In₂O₃, MgO, BaO and MoO₃ are advantageous over the others, and more advantageous antistatic agents are SnO₂, ZnO, In₂O₃ and TiO₂, especially SnO_{2.}

Additionally, in the case of applying the laser thermal transfer recording method to the present thermal transfer material, it is appropriate that the antistatic agent used in the backing layer be transparent in a substantial sense to enable transmission of laser light.

The smaller grain size the conductive metal oxide used as antistatic agent has, the more advantageous it is from the viewpoint of minimizing light scattering. And it is required that the grain size of conductive metal oxide be determined using as a parameter the ratio between the refractive index of grain and the refractive index of binder, and the grain size can be evaluated by the use of Mie's theory. In general, the suitable average grain size is from 0.001 to 0.5 μm, preferably from 0.003 to 0.2 μm. The term “average grain size” as used herein refers to the mean value of sizes of not only primary grains but also grains having higher-order structures.

In addition to an antistatic agent, various additives, such as a surfactant, a slip additive and a matting agent, and binder can be added to the backing layer.

Examples of a binder usable for formation of the backing layer include homo-and copolymers of acrylic acid monomers such as acrylic acid, methacrylic acid, acrylate and methacrylate, cellulose polymers such as nitrocellulose, methyl cellulose, ethyl cellulose and cellulose acetate, vinyl polymers and copolymers of vinyl compounds such as polyethylene, polypropylene, polystyrene, vinyl chloride copolymers including vinyl chloride-vinyl acetate copolymer, polyvinyl pyrrolidone, polyvinyl butyral and polyvinyl alcohol, condensation polymers such as polyester, polyurethane and polyamide, thermoplastic rubber polymers such as butadiene-styrene copolymer, polymers obtained by polymerizing and cross-linking photopolymerizable or thermopolymerizable compounds such as epoxy compounds, and melamine compounds.

(Photothermal Converting Layer)

The photothermal converting layer comprises a light-to-heat converting substance and a binder. Further, it can contain a matting agent, if needed. Furthermore, it may contain other components, if desired.

The light-to-heat converting substance is a material having the function of converting the energy of irradiated light to thermal energy. In general, the materials having such a function are dyes (including pigments, and hereinafter the term “dyes” is intended to include pigments also) capable of absorbing laser light. When images are recorded with infrared laser, it is appropriate to use infrared absorbing dyes as the light-to-heat converting substance. Examples of dyes usable as such a substance include black pigments such as carbon black, pigments of macrocyclic compounds having their absorption in the visible to near infrared regions, such as phthalocyanine and naphthlocyanine, organic dyes used as laser absorbing materials for high-density laser recording such as an optical disk (e.g., cyanine dyes such as indolenine dyes, anthraquinone dyes, azulene dyes, phthalocyanine dyes), and organometallic compound dyes such as dithiol-nickel complex. Of these dyes, cyanine dyes are preferred over the others. This is because they have high absorption constants in the infrared region, thereby enabling a reduction in the thickness of the photothermal converting layer when they are used as a light-to-heat converting substance; as a result, the recording sensitivity of the thermal transfer sheet can be enhanced.

Besides the dyes as recited above, inorganic materials including particulate metallic substances such as blackened silver can be used as light-to-heat converting substances.

As a binder contained in the photothermal converting layer, resins having strength enabling at least the formation of a layer on the substrate and high thermal conductivity are suitable. Further, it is desired for those resins to have heat resistance and not to decompose by heat produced from the light-to-heat converting substance at the time when images are recorded. This is because such resins make it possible to retain the surface smoothness of the photothermal converting layer after irradiation with high-energy light. Specifically, the resins suitable as the binder are resins having thermal decomposition temperature of at least 400° C., preferably 500° C. or above. The term “thermal decomposition temperature” used herein is defined as the temperature at which a 5% reduction in the weight of a resin is caused when the resin undergoes thermogravimetric analysis in a stream of air at a temperature-rise speed of 10° C./min. Further, it is appropriate that the binder have a glass transition temperature of 200 to 400° C., preferably 250 to 35° C. When the glass transition temperature of the binder is lower than 200° C., the images formed tend to suffer fogging; while, when the binder has a glass transition temperature higher than 400° C., the solubility thereof is low, and so the production efficiency is apt to be decreased.

Additionally, it is appropriate that the heat resistance (e.g., thermal deformation temperature, thermal decomposition temperature) of the binder in the photothermal converting layer be higher than those of materials used in other layers provided on the photothermal converting layer.

Examples of a binder usable in the photothermal converting layer include acrylic acid resins such as polymethyl methacrylate, polycarbonate, vinyl resins such as polystyrene, vinyl chloride-vinyl acetate copolymer and polyvinyl alcohol, polyvinyl butyral, polyester, polyvinyl chloride, polyamide, polyimide, polyetherimide, polysulfone, polyether sulfone, aramide, polyurethane, epoxy resin, and urea-melamine resin.

Of these resins, polyimide resin is preferred over the others.

In particular, the polyimide resins represented by formulae (I) to (IV) are beneficial, because they are soluble in organic solvents and enable improvement in thermal transfer sheet productivity. Further, these polyimide resins are advantageous in that they can ensure improvements in viscosity stability, long-term keeping quality and moisture resistance of the coating composition for the photothermal converting layer.

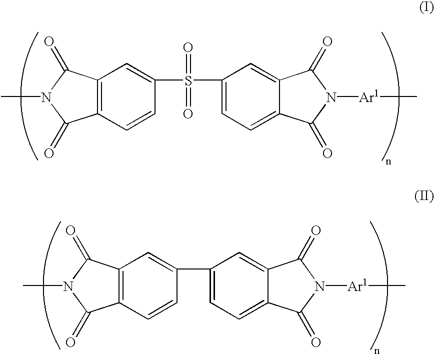

In the above formulae (I) and (II), Ar¹ represents an aromatic group of formula (1), (2) or (3) illustrated below, and n represents an integer of 10 to 100.

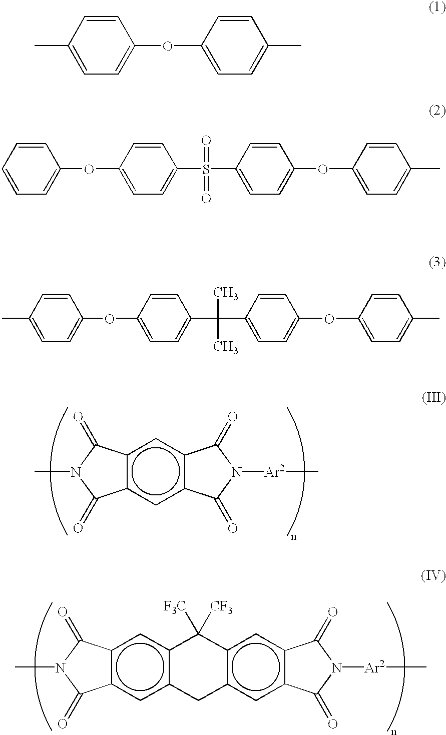

In the above formulae (III) and (IV), Ar represents an aromatic group of formula (4), (5), (6) or (7) illustrated below, and n represents an integer of 10 to 100.

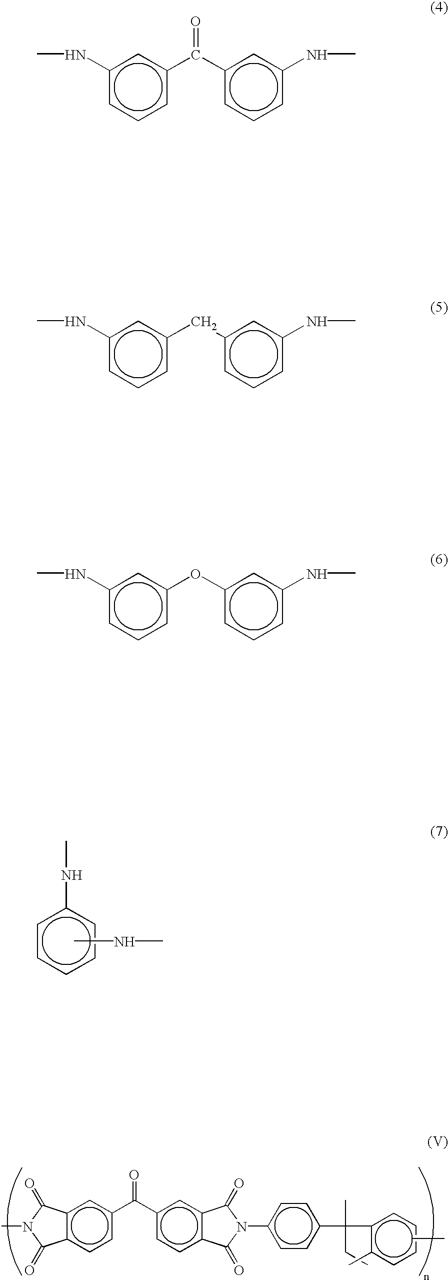

In the above formulae (V) to (VII), n and m each represent an integer of 10 to 100. In the formula (VI), the ratio between n and m is from 6:4 to 9:1.

Additionally, one measure of judgement as to the solubility of a resin in an organic solvent is whether or not at least 10 parts by weight of the resin dissolves in 100 parts by weight of N-methylpyrrolidone at 25° C. If the proportion of a resin dissolved is at least 10 parts by weight, the resin is suitable as binder for the photothermal converting layer. The resins more suitable as the binder are those dissolving in proportions of no lower than 100 parts by weight in 100 parts by weight of N-methylpyrrolidone.

As a matting agent contained in the photothermal converting layer, inorganic fine particles and organic fine particles can be used. Examples of inorganic fine particles usable as the matting agent include metal salts such as silica, titanium dioxide, aluminum oxide, zinc oxide, magnesium oxide, barium sulfate, magnesium sulfate, aluminum hydroxide, magnesium hydroxide and boronnitride, kaolin, clay, talc, zinc white, white lead, sieglite, quartz, diatomaceous earth, barite, bentonite, mica and synthetic mica. Examples of organic fine particles usable as the matting agent include resin particles, such as fluorine-contained resin particles, guanamine resin particles, acrylic resin particles, styrene-acrylic copolymer resin particles, silicone resin particles, melamine resin particles and epoxy resin particles.

The particle size of a matting agent is generally from 0.3 to 30 μm, preferably from 0.5 to 20 μm, and the suitable amount of matting agent added is from 0.1 to 100 mg/M².

To the photothermal converting layer, a surfactant, a thickening agent and an antistatic agent may further be added, if desired.

The photothermal converting layer can be provided by coating on a substrate a coating composition prepared by dissolving a light-to-heat converting substance and a binder in an appropriate solvent, and further adding thereto a matting agent and other additives, if needed, and then drying the coating composition. Examples of an organic solvent usable for dissolution of polyimide resin include n-hexane, cyclohexane, diglime, xylene, toluene, ethyl acetate, tetrahydrofuran, methyl ethyl ketone, acetone, cyclohexanone, 1,4-dioxane, 1,3-dioxane, dimethyl acetate, N-methyl-2-pyrollidone, dimethyl sulfoxide, dimethylformamide, dimethylacetamide, γ-butyrolactone, ethanol and methanol. The coating and drying of the coating composition can be carried out in usual manners. Specifically, the drying is carried out at a temperature of 300° C. or below, preferably 200° C. or below. When polyethylene terephthalate is used as the substrate, the drying temperature is preferably from 80 to 150° C.

When the proportion of the binder in the photothermal converting layer is too low, the photothermal converting layer has low cohesive strength; as a result, when the images formed thereon are transferred to an image-receiving layer, the photothermal converting layer tends to be transferred together with the images to cause color mixing in the transferred images. When the proportion of polyimide resin is too high, an increase in thickness is required for the photothermal converting layer to attain the desired level of absorptivity. As a result, reduction in sensitivity is apt to be caused. The suitable ratio between the weights of the light-to-heat converting substance and the binder on a solid basis is from 1:20 to 2:1, particularly preferably from 1:10 to 2:1.

It is advantageous to reduce a thickness of the photothermal converting layer because, as mentioned above, the sensitivity of the thermal transfer sheet can be enhanced. The suitable thickness of the photothermal converting layer is from 0.03 to 1.0 μm, preferably from 0.05 to 0.5 μm. Further, it is appropriate that the photothermal converting layer have laser light absorption in the wavelength region of 700 to 1,500 nm, particularly 750 to 1,000 nm. In addition, it is advantageous that the photothermal converting layer has an optical density of 0.7 to 1.1,preferably 0.8 to 1.0, when the light of a wavelength of 830 nm is incident thereon. As far as the photothermal converting layer has such an optical density, the transfer sensitivity of an image-forming layer provided thereon can be increased. When the optical density at the wavelength of 830 nm is lower than 0.7, conversion of the irradiated light to heat becomes insufficient, so the transfer sensitivity tends to be lowered. On the other hand, the optical density higher than 1.1 has an influence on functions of the photothermal converting layer at the time when recording is performed. So fogging is apt to occur in such a case.

(Image-Forming Layer)

The image-forming layer contains at least pigments to be transferred to an image-receiving sheet to form images, and further a binder for layer formation, and other ingredients as required.

The pigments are broadly divided into organic pigments and inorganic pigments. The former can ensure high transparency in the coating, while the latter can produce excellent masking effect. So the pigments may be selected properly depending on the intended purpose. When the thermal transfer sheet is used as color proof in graphic arts, organic pigments having yellow, magenta, cyan and black hues or hues close thereto, which are generally used for printing ink, are used to advantage. In some cases, metal powders and fluorescent pigments can be used, too. Suitable examples of organic pigments include azo pigments, phthalocyanine pigments, anthraquinone pigments, dioxazine pigments, quinacridone pigments, isoindolinone pigments and nitro pigments. More specifically, examples of pigments usable in the image-forming layer are recited below on a hue-by-hue basis. However, these examples should not be construed as limiting the pigments usable in the invention.

1) Yellow Pigments

Pigment Yellow 12 (C.I. No. 21090), with examples including Permanent Yellow DHG (produced by Clariant Japan Co. Ltd.), Lionol Yellow 1212B (produced by Toyo Ink Mfg. Co., Ltd.), Irgalite Yellow LCT (produced by Ciba Specialty Chemical Co., Ltd.) and Symuler Fast Yellow GTF 219 (produced by Dai-Nippon Ink & Chemicals, Inc.).

Pigment Yellow 13 (C.I. No. 21100), with examples including Permanent Yellow GR (produced by Clariant Japan Co. Ltd.) and Lionol Yellow 1313 (produced by Toyo Ink Mfg. Co., Ltd.).

Pigment Yellow 14 (C.I. No. 21095), with examples including Permanent Yellow G (produced by Clariant Japan Co. Ltd.), Lionol Yellow 1401-G (produced by Toyo Ink Mfg. Co., Ltd.), Seika Fast Yellow 2270 (produced by Dainichiseika C. & C. Mfg. Co., Ltd.) and Symuler Fast Yellow 4400 (produced by Dai-Nippon Ink & Chemicals, Inc.).

Pigment Yellow 17 (C.I. No. 21105), with examples including Permanent Yellow GG02 (produced by Clariant Japan Co. Ltd.) and Symuler Fast Yellow 8GF (produced by Dai-Nippon Ink & Chemicals, Inc.).

Pigment Yellow 155, such as Graphtol Yellow 3GP (produced by Clariant Japan Co. Ltd.)

Pigment Yellow 180 (C.I. No. 21290), with examples including Novoperm Yellow P-HG (produced by Clariant Japan Co. Ltd.) and PV Fast Yellow HG (produced by Clariant Japan Co. Ltd.).

Pigment Yellow 139 (C.I. No. 56298), such as Novoperm Yellow M2R 70 (produced by Clariant Japan Co. Ltd.).

2) Magenta Pigments

Pigment Red 57:1 (C.I. No. 15850:1), with examples including Graphtol Rubine L6B (produced by Clariant Japan Co. Ltd.), Lionol Red 6B-4290G (produced by Toyo Ink Mfg. Co., Ltd.), Irgalite Rubine 4BL (produced by Ciba Specialty Chemical Co., Ltd.) and Symuler Brilliant Carmine 6B-229 (produced by Dai-Nippon Ink & Chemicals, Inc.).

Pigment Red 122 (C.I. No. 73915), with examples including Hosterperm Pink E (produced by Clariant Japan Co. Ltd.), Lionogen Magenta 5790 (produced by Toyo Ink Mfg. Co., Ltd.) and Fastogen Super Magenta RH (produced by Dai-Nippon Ink & Chemicals, Inc.).

Pigment Red 53:1 (C.I. No. 15585:1), with examples including Permanent Lake Red LCY (produced by Clariant Japan Co. Ltd.) and Symuler Lake Red C conc (produced by Dai-Nippon Ink & Chemicals, Inc.).

Pigment Red 48:1 (C.I. No. 15865:1), with examples including Lionol Red 2B 3300 (produced by Toyo Ink Mfg. Co., Ltd.) and Symuler Red NRY (produced by Dai-Nippon Ink & Chemicals, Inc.).

Pigment Red 48:2 (C.I. No. 15865:2), with examples including Permanent Red W2T (produced by Clariant Japan Co. Ltd.), Lionol Red LX235 (produced by Toyo Ink Mfg. Co., Ltd.) and Symuler Red 3012 (produced by Dai-Nippon Ink & Chemicals, Inc.).

Pigment Red 48:3 (C.I. No. 15865:3), with examples including Permanent Red 3RL (produced by Clariant Japan Co. Ltd.) and Symuler Red 2BS (produced by Dai-Nippon Ink & Chemicals, Inc.).

Pigment Red 177 (C.I. No. 65300), such as Cromophthal Red A2B (produced by Ciba Specialty Chemicals Co., Ltd.).

3) Cyan Pigments

Pigment Blue 15 (C.I. No. 74160), with examples including Lionol Blue 7027 (produced by Toyo Ink Mfg. Co., Ltd.) and Fastogen Blue BB (produced by Dai-Nippon Ink & Chemicals, Inc.)

Pigment Blue 15:1 (C.I. No. 74160), with examples including Hosterperm Blue A2R (produced by Clariant Japan Co. Ltd.) and Fastogen Blue 5050 (produced by Dai-Nippon Ink & Chemicals, Inc.).

Pigment Blue 15:2 (C.I. No. 74160), with examples including Hosterperm Blue AFL (produced by Clariant Japan Co. Ltd.), Irgalite Blue BSP (produced by Ciba Specialty Chemicals Co., Ltd.) and Fastogen Blue GP (produced by Dai-Nippon Ink & Chemicals, Inc.).

Pigment Blue 15:3 (C.I. No. 74160), with examples including Hosterperm Blue B2G (produced by Clariant Japan Co. Ltd.), Lionol Blue FG7330 (produced by Toyo Ink Mfg. Co., Ltd.), Cromophthal Blue 4GNP (produced by Ciba Specialty Chemicals Co., Ltd.) and Fastogen Blue FGF (produced by Dai-Nippon Ink & Chemicals, Inc.).

Pigment Blue 15:4 (C.I. No. 74160), with examples including Hosterperm Blue BFL (produced by Clariant Japan Co. Ltd.), Cyanine Blue 700-10FG (produced by Toyo Ink Mfg. Co., Ltd.), Irgalite Blue GLNF (producedby Ciba Specialty Chemicals Co., Ltd.) and Fastogen Blue FGS (produced by Dai-Nippon Ink & Chemicals, Inc.).

Pigment Blue 15:6 (C.I. No. 74160), such as Lionol Blue ES (produced by Toyo Ink Mfg. Co., Ltd.).

Pigment Blue 60 (C.I. No. 69800), with examples including Hosterperm Blue RL01 (produced by Clariant Japan Co. Ltd.) and Lionogen Blue 6501 (produced by Toyo Ink Mfg. Co., Ltd.).

4) Red Pigments

C.I. Pigment Red 97, C.I. Pigment Red 122, C.I. Pigment Red 149, C.I. Pigment Red 168, C.I. Pigment Red 177, C.I. Pigment Red 180, C.I. Pigment Red 192, C.I. Pigment Red 215, and organic pigments such as C.I. No. 12085, C.I. 12120, C.I. No. 12140 and C.I. No. 12315.

5) Green Pigments

C.I. Pigment Green 7, C.I. Pigment Green 36, and organic pigments such as C.I. No. 42053, C.I. No. 42085 and C.I. No. 42095.

6) Blue Pigments

C.I. Pigment Blue 15:1, C.I. Pigment Blue 15:4, C.I. Pigment Blue 15:6, C.I. Pigment Blue 22, C.I. Pigment Blue 60, C.I. Pigment Blue 64, and organic pigments such as C.I. No. 42052 and C.I. No. 42090.

7) Black Pigments

Pigment Black 7 (C.I. No. 77266), with examples including Mitsubishi Carbon Black MA100 (produced by Mitsubishi Chemical Corporation), Mitsubishi Carbon Black #5 (produced by Mitsubishi Chemical Corporation) and Black Pearls 430 (produced by Cabot Co.).

Further, the pigments used in the invention may be selected appropriately from commercially available pigments by reference to books, e.g., Ganryo Binran (which means “Handbook of Pigments”, translated into English), compiled by Nippon Ganryo Gijutu Kyokai, published by Seibundo Shinkosha in 1989, and Colour Index, The Society of Dyes & Colourist, 3rd Ed., 1987.

It is appropriate that the pigments as recited above have an average particle size of 0.03 to 1 μm, preferably 0.05 to 0.5 μm.

When the average particle size is smaller than 0.03 μm, the cost of dispersing such pigments is increased and the dispersions obtained are subject to gelation. When the average particle size is increased beyond 1 μm, on the other hand, coarse particles in the pigments tend to inhibit a good contact between the image-forming layer and the image-receiving layer and, in some cases, further impair transparency of the image-forming layer.

Binders suitable for the image-forming layer are amorphous organic high polymers having softening points in the range of 40 to 150° C. Examples of such high polymers include butyral resin, polyamide resin, polyethyleneimine resin, sulfonamide resin, polyesterpolyol resin, petroleum resin, homo-or copolymers of monomers selected from among styrene, styrene derivatives or substituted styrenes (such as styrene, vinyltoluene, α-methylstyrene, 2-methylstyrene, chloro-styrene, vinylbenzoic acid, sodium vinylbenzenesulfonate and aminostyrene), homopolymers of vinyl monomers (with examples including methacrylates such as methyl methacrylate, ethyl methacrylate, butyl methacrylate and hydroxyethyl methacrylate, acrylates such as methyl acrylate, ethyl acrylate, butyl acrylate and α-ethylhexyl acrylate, dienes such as butadiene and isoprene, acrylonitrile, vinyl ethers, maleic acid and maleates, maleic anhydride, succinic acide, vinyl chloride and vinyl acetate) and copolymers of vinyl monomers as recited above and other monomers. These resins may be used alone or as mixtures of two or more thereof.

The suitable proportion of pigments in the image-forming layer is from 30 to 80% by weight, preferably 30 to 50% by weight. And the suitable proportion of resins in the image-forming layer is from 70 to 30% by weight, preferably from 70 to 40% by weight.

The image-forming layer can contain as the other ingredients the following substances.

(1) Various Kinds of Wax

Wax includes mineral wax, natural wax and synthetic wax. As examples of mineral wax, mention may be made of petroleum wax, such as paraffin wax, microcrystalline wax, ester wax and oxidized wax, montan wax, ozokerite, and ceresin. Among them, paraffin wax is preferred in particular. The paraffin wax is isolated from petroleum, and products having various melting points are on the market.

Examples of natural wax include vegetable wax, such as carnauba wax, Japan tallow, auricurie wax and espal wax, and animal wax such as beeswax, insect wax, shellac wax and whale wax.

Synthetic wax is generally used as slip additive, and includes higher fatty acid compounds. As examples of such higher fatty acid compounds, mention may be made the following compounds.

1) Fatty Acid Wax

Linear saturated fatty acids represented by the following formula:

CH₃(CH₂)ₙCOOH

wherein n is an integer of 6 to 28. Examples thereof include stearic acid, behenic acid, palmitic acid, 12-hydroxystearic acid and azelaic acid.

Further, such fatty acids may take the form of metal salts (e.g., K, Ca, Zn and Mg salts).

2) Fatty Acid Ester Wax

Examples of fatty acid esters include ethyl stearate, lauryl stearate, ethyl behenate, hexyl behenate and behenyl myristate.

3) Fatty Acid Amide Wax

Examples of fatty acid amides include stearic acid amide and lauric acid amide.

4) Aliphatic Alcohol Wax

Linear saturated aliphatic alcohol compounds represented by the following formula:

CH₃(CH₂)ₙOH

wherein n is an integer of 6 to 28. As an example of such alcohol, mention may be made of stearyl alcohol.

Of the foregoing kinds of synthetic wax 1) to 4), higher fatty acid amides, such as stearic acid amide and lauric acid amide, are preferred over the others. The wax compounds as recited above can be used alone or as appropriate combinations.

(2) Plasticizers

Plasticizers suitable for the image-forming layer are ester compounds known as plasticizers, with examples including aliphatic dibasic acid esters, such as phthalates (e.g., dibutyl phthalate, di-n-octyl phthalate, di (2-ethylhexyl) phthalate, dinonyl phthalate, dilauryl phthalate, butyl lauryl phthalate, butyl benzyl phthalate), di(2-ethylhexyl) adipate and di (2-ethylhexyl) cebacate, phosphoric acid triesters such as tricresyl phosphate and tri(2-ethylhexyl) phosphate, polyolpolyesters such as polyethylene glycol esters, and epoxy compounds such as epoxyfatty acid esters. Of these ester compounds, esters of vinyl monomers, especially esters of acrylic and methacrylic acids, are preferred over the others from the viewpoints of improvement in transfer sensitivity, reduction in nonuniform transfer and extent to which they can influence the control of elongation at break.

As examples of ester compounds of acrylic or methacrylic acid, mention may be made of polyethylene glycol dimethacrylate, 1,2,4-butanetriol trimethacrylate, trimethylolethane triacrylate, pentaerythritol acrylate, pentaerythritol tetraacrylate and dipentaerythritol polyacrylate.

The plasticizers used herein may be polymers, too. In particular, polyesters are preferred because of their great addition effect and resistance to diffusion under storage conditions. As examples of polyesters usable herein, mention may be made of polyesters of sebacate type and polyesters of adipate type.

Additionally, additives which may be added to the image-forming layer should not be construed as being limited to the additives as recited above. Further, the foregoing plasticizers may be used alone or as mixtures thereof.

When the amount of the foregoing additives contained in the image-forming layer is too large, it tends to occur that the resolution of transferred images is lowered, the film strength of the image-forming layer itself is decreased or the unexposed areas of the image-forming layer is transferred to the image-receiving sheet because of reduction in adherence of the image-forming layer to the photothermal converting layer. From these viewpoints, it is appropriate that the amount of wax contained be from 0.1 to 30%, preferably from 1 to 20%, of the weight of the total solids in the image-forming layer and the amount of plasticizers contained be from 0.1 to 20%, preferably from 0.1 to 10%, of the weight of the total solids in the image-forming layer.

(3) Others

In addition to the ingredients as recited above, the image-forming layer may further contain a surfactant, inorganic or organic fine particles (e.g., metal powders, silica gel), oils (e.g., linseed oil, mineral oil), a thickener and an anti-static agent. By containing substances capable of absorbing light of the same wavelengths as the light source used for image recording has, energy required for transfer can be reduced, except the case of forming black images. As substances capable of absorbing light of the wavelengths corresponding to those of the light source used, both pigments and dyes may be used. In the case of forming color images, the use of an infrared light source, such as semiconductor laser, for image recording and dyes showing no absorption in the visible region but strong absorption at the wavelengths of the light source used is advantageous from the viewpoint of color reproduction. As examples of near infrared dyes, mention may be made of the compounds described in JP-A-3-103476.

The image-forming layer can be provided by coating a coating composition, in which pigments, binder and other additives are dissolved or dispersed, on the photothermal converting layer (or a heat-sensitive delaminating layer as described below, if provided on the photothermal converting layer), and then drying the composition coated. Examples of a solvent usable for preparing the coating composition include n-propyl alcohol, methyl ethyl ketone, propylene glycol monomethyl ether (MFG), methanol and water. The coating and drying of the coating composition can be effected in usual ways.

(Cushion Layer)

It is advantageous to provide a cushion layer having a function of cushioning between the substrate and the photothermal converting layer, particularly when a color filter is formed on the image-receiving sheet. When the cushion layer is provided, the degree of contact of the image-forming layer with the image-receiving layer upon laser thermal transfer can be heightened to result in improvement of image quality. In addition, even when a foreign matter is trapped between the thermal transfer sheet and the image-receiving sheet, the gap between these sheets can be lessened by a deforming action of the cushion layer; as a result, the sizes of image defects, such as clear, can be reduced.

The cushion layer is constituted so as to permit easy deformation when a stress is applied to the interface. In order to achieve the foregoing effect, it is appropriate that the cushion layer be made up of a material having a low elasticity modulus, a material having rubber-like elasticity or a thermoplastic resin capable of softening with ease by heating. The suitable elasticity modulus of the cushion layer at room temperature is from 0.5 MPa to 1.0 GPa, preferably from 1 MPa to 0.5 GPa, particularly preferably from 10 MPa to 100 MPa. For sinking a foreign matter, such as dust, into the cushion layer, it is appropriate that the consistency of the cushion layer be at least 10 when determined under the condition of 25° C., 100 g and 5 seconds in accordance with JIS K2530. The suitable glass transition temperature of the cushion layer is 80° C. or below, preferably 25° C. or below, and the suitable softening point of the cushion layer is from 50 to 200° C. Adjustment of these physical properties, e.g., Tg can be effectively attained by adding a plasticizer to a binder.

Examples of a material usable as binder of the cushion layer include rubbers such as urethane rubber, butadiene rubber, nitrile rubber, acrylic rubber and natural rubber, polyethylene, polypropylene, polyester, styrene-butadiene copolymer, ethylene-vinyl acetate copolymer, ethylene-acrylic copolymer, vinyl chloride-vinyl acetate copolymer, vinylidene chloride resin, plasticizer-impregnated vinyl chloride resin, polyamide resin and phenol resin.

The suitable thickness of the cushion layer, though it varies depending on the resin used and other conditions, is generally from 3 to 100 μm, preferably from 10 to 52 μm

On the photothermal converting layer of the thermal transfer sheet, it is possible to provide a heat-sensitive delaminating layer containing a heat-sensitive material capable of liberating a gas or releasing attached water by the action of heat produced in the photothermal converting layer and thereby weakening the bonding strength between the photothermal converting layer and the image-forming layer. Examples of such a heat-sensitive material include compounds capable of decomposing or changing their properties upon heating to liberate gasses (which may be either polymeric or low molecular weight compounds), and compounds absorbing or adsorbing a considerable amount of easily vaporized liquid such as water (which maybe either polymeric or low molecular weight compounds) . These compounds may be used as mixtures thereof.

As examples of polymers capable of liberating gasses through decomposition or change in their properties when they are heated, mention may be made of self-oxidative polymers such as nitrocellulose, halogen-containing polymers such as chlorinated polyolefin, chlorinated rubber, rubber polychloride, polyvinyl chloride and polyvinylidene chloride, acrylic polymers such as polyisobutyl methacrylate to which a volatile compound like water is adsorbed, cellulose esters such as ethyl cellulose to which a volatile compound like water is adsorbed, and natural high molecular compounds such as gelatin to which a volatile compound like water is adsorbed. As examples of low molecular weight compounds capable of liberating gasses through decomposition or change in their properties when they are heated, mention may be made of compounds capable of producing gasses by exothermic decomposition, such as diazo compounds and azide compounds.

Of the heat-sensitive materials as recited above, the compounds causing thermal decomposition or thermal change in properties at a temperature of 280° C. or below, particularly 230° C. or below, are used to advantage.

When low molecular weight compounds are used as heat-sensitive materials in the heat-sensitive delaminating layer, it is appropriate to use them in combination with binders. As these binders, the polymers which themselves undergo thermal decomposition or cause thermal change in their properties to evolve gasses can be used. However, ordinary binders free of the foregoing features may also be used. In the combined use of a heat-sensitive low molecular weight compound and a binder, it is appropriate that the ratio of the former to the latter be from 0.02:1 to 3:1, preferably from 0.05:1 to 2:1, by weight. It is desirable that the heat-sensitive delaminating layer be spread on almost all the surface of the photothermal converting layer and the thickness thereof be generally from 0.03 to 1 μm, preferably from 0.05 to 0.5 μm.

In the case of a thermal transfer sheet having a structure that the substrate is provided sequentially with a photothermal converting layer, a heat-sensitive delaminating layer and an image-forming layer, the heat-sensitive delaminating layer decomposes or changes its property by the heat transferred from the photothermal converting layer to result in evolution of gas. By the decomposition or the evolution of gas, the heat-sensitive delaminating layer disappears in part, or aggregative destruction occurs in the heat-sensitive delaminating layer to lower the binding power between the photothermal converting layer and the image-forming layer. Depending on the behavior of the heat-sensitive delaminating layer, therefore, partial adhesion of the heat-sensitive delaminating layer to the image-forming layer may occur and manifest itself on the surface of finally formed images to make color stain on the images. For this reason, it is desirable for the heat-sensitive delaminating layer to be almost colorless, or high in visible light transmittance, so that no visible color stain is made on the finally formed images even when partial transfer of the heat-sensitive delaminating layer occurs. Specifically, it is appropriate that the heat-sensitive delaminating layer have absorptivity of at most 50%, preferably at most 10%, with respect to visible light.

Additionally, it is possible to design the photothermal converting layer so as to function also as a heat-sensitive delaminating layer instead of forming an independent heat-sensitive delaminating layer in the thermal transfer sheet. In this case, the heat-sensitive material as recited above is added to a coating composition for the photothermal converting layer.

It is advantageous that the static friction coefficient of the outermost layer of the thermal transfer sheet on the image-forming layer provided side is adjusted to at most 0.35, preferably at most 0.20. By controlling the static friction coefficient of the outermost layer to 0.35 or below, roll stains ascribable to conveyance of the thermal transfer sheet can be reduced, and thereby the images formed can have high quality. The static friction coefficient can be determined using the method described in Japanese Patent Application No. 2000-85759, paragraph [0011].

It is advantageous that the image-forming layer surface has a Smooster value of 0.5 to 50 mmHg (≈0.0665 to 6.65 kPa) under a condition of 23° C.-55% RH and the Ra thereof is from 0.05 to 0.4 μm. Such surface smoothness enables reduction in number of microgaps present at the contact face between the image-receiving layer and the image-forming layer, so it is beneficial to not only transfer capability but also image quality. The Ra value can be measured with a surface roughness tester (Surfcom, made by Tokyo Seiki K.K.) based on JIS B0601. It is appropriate that the surface hardness of the image-forming layer be at least 10 g as measured with a sapphire stylus. Further, it is appropriate that the image-forming layer have an electric potential of −100 to 100 V at the time when 1 second has elapsed since the thermal transfer sheet was grounded after electrification according to The U.S. Federal Government Testing Standards 4046. The suitable surface resistance of the image-forming layer is at most 10⁹ Ω under a condition of 23° C.-55% RH.

An image-receiving sheet used in combination with the foregoing thermal transfer sheet is illustrated below.

[Image-Receiving Sheet]

(Layer Structure)

The image-receiving sheet has a layer structure that at least one image-receiving layer is provided on a support, preferably a polyether sulfone support, and further at least one layer selected from a cushion layer, a release layer or an interlayer may be provided between the support and the image-receiving layer, if desired. In addition, it is advantageous in point of conveyance that the image-receiving sheet has a backing layer on the side opposite to the image-receiving layer.

(Support)

Into a polyether sulfone support, fine voids may be introduced, if desired. Further, known additives maybe added to the support, if needed.

The support thickness in the image-receiving sheet is generally from 10 to 400 μm, preferably from 25 to 200 μm. For the purpose of bringing the support surface into a close contact with the image-receiving layer (or a cushion layer) or the image-forming layer of the thermal transfer sheet, the support may be subjected to surface treatment such as corona discharge treatment or glow discharge treatment.

(Image-Receiving Layer)

It is desirable for the image-receiving sheet to have at least one image-receiving layer on the support in order to fix the image-forming layer transferred to the surface thereof. The image-receiving layer is preferably a layer constituted mainly of an organic polymer binder. Polymers suitable as such a binder are thermoplastic resins with examples including homo-and copolymers of acrylic monomers such as acrylic acid, methacrylic acid, acrylate and methacrylate, cellulose polymers, such as methyl cellulose, ethyl cellulose and cellulose acetate, homo-and copolymers of vinyl monomers, such as polystyrene, polyvinyl pyrrolidone, polyvinyl butyral, polyvinyl alcohol and polyvinyl chloride, condensation polymers, such as polyester and polyamide, and rubber polymers, such as butadiene-styrene copolymer. The binder of the image-receiving layer is preferably a polymer having a glass transition temperature (Tg) lower than 90° C. in order to ensure proper adherence to the image-forming layer. For this purpose, it is possible to add a plasticizer to the image-receiving layer. In order to prevent blocking between sheets, on the other hand, it is appropriate for the binder polymer to have a glass transition temperature of no lower than 30° C. For the purpose of enhancing the contact of the image-receiving layer with the image-forming layer at the time of laser recording and achieving improved sensitivity and image strength, it is advantageous in particular that the binder polymer of the image-receiving layer is the same or similar binder polymer used in the image-forming layer.

It is advantageous that the image-receiving layer surface has a Smooster value of 0.5 to 50 mmHg (≈0.0665 to 6.65 kPa) under a condition of 23° C.-55% RH and the Ra thereof is from 0.05 to 0.4 μm. Such surface smoothness enables reduction in number of microgaps present at the contact face between the image-receiving layer and the image-forming layer, so it is beneficial to not only transfer capability but also image quality. The Ra value can be measured with a surface roughness tester (Surfcom, made by Tokyo Seiki K.K.) based on JISB0601. Further, it is appropriate that the image-receiving layer have an electric potential of −100 to 100 V at the time when 1 second has elapsed since the image-receiving sheet was grounded after electrification according to The U.S. Federal Government Testing Standards 4046. The suitable surface resistance of the image-receiving layer is at most 10⁹ Ω under a condition of 23° C.-55% RH. It is advantageous that the static friction coefficient of the image-receiving layer surface is at most 0.2 and the surface energy thereof is from 23 to 35 mg/M².

In the case where images once formed on the image-receiving layer are re-transferred to another support such as printing paper or glass substrate, it is also advantageous that at least one image-receiving layer is formed from a light-curable material. As an example of such a light-curable material, mention may be made of a composition comprising (a) at least one photopolymerizing monomer selected from polyfunctional vinyl or vinylidene compounds capable of forming photopolymers by addition polymerization, (b) an organic polymer, (c) a photopolymerization initiator and, if desired, additives including a thermopolymerization inhibitor. Examples of a polyfunctional vinyl monomer usable therein include unsaturated esters of polyols, especially esters of acrylic or methacrylic acid (e.g., ethylene glycol diacrylate, pentaerythritol tetraacrylate).

As examples of an organic polymer (b), mention may be made of the polymers recited above as a binder for forming the image-receiving layer. As to the photopolymerization initiator (c), a general radical photopolymerization initiator, such as benzophenone or Michler's ketone, is used in a proportion of 0.1 to 20 weight % to the layer.

The thickness of the image-receiving layer is from 0.3 to 7 μm, preferably from 0.7 to 4 μm. When the thickness is thinner than 0.3 μm, the image-receiving layer is easily broken upon re-transfer to printing paper owing to lack of film strength. When the image-receiving layer is too thick, on the other hand, it causes an increase in glossiness of images re-transferred to printing paper and thereby the closeness of the images to printed matter is lowered.

(Other Layers)

Between the support and the image-receiving layer, a cushion layer may be provided. When the cushion layer is provided, the degree of contact of the image-forming layer with the image-receiving layer upon laser thermal transfer can be heightened to result in improvement of image quality. In addition, even when a foreign matter is trapped between the thermal transfer sheet and the image-receiving sheet, the gap between these sheets can be lessened by a deforming action of the cushion layer; as a result, the sizes of image defects, such as clear, can be reduced. Further, when the images formed by transfer are re-transferred to printing paper prepared separately, the cushion layer enables the image-receiving surface to be deformed depending on asperities on the printing paper surface and improves the transferability to the image-receiving layer. Furthermore, the cushion layer can lower the glossiness of the re-transferred images and improve the clossness to printed matter.

The cushion layer is constituted so as to permit easy deformation when a stress is applied to the image-receiving layer. In order to achieve the foregoing effect, it is appropriate that the cushion layer be made up of a material having a low elasticity modulus, a material having rubber-like elasticity or a thermoplastic resin capable of softening with ease by heating. The suitable elasticity modulus of the cushion layer at room temperature is from 0.5 MPa to 1.0 GPa, preferably from 1 MPa to 0.5 GPa, particularly preferably from 10 MPa to 100 MPa. For sinking a foreign matter, such as dust, into the cushion layer, it is appropriate that the consistency of the cushion layer be at least 10 when determined under the condition of 25° C., 100 g and 5 seconds in accordance with JIS K2530. The suitable glass transition temperature of the cushion layer is 80° C. or below, preferably 25° C. or below, and the suitable softening point of the cushion layer is from 50 to 200° C. Adjustment of these physical properties, e.g., Tg can be effectively attained by adding a plasticizer to a binder.

Examples of a material usable as binder of the cushion layer include rubbers such as urethane rubber, butadiene rubber, nitrile rubber, acrylic rubber and natural rubber, polyethylene, polypropylene, polyester, styrene-butadiene copolymer, ethylene-vinyl acetate copolymer, ethylene-acrylic copolymer, vinyl chloride-vinyl acetate copolymer, vinylidene chloride resin, plasticizer-impregnated vinyl chloride resin, polyamide resin and phenol resin.

The suitable thickness of the cushion layer, though it varies depending on the resin used and other conditions, is generally from 3 to 100 μm, preferably from 10 to 52 μm.

Although it is required for the image-receiving layer and the cushion layer to be bonded to each other up to the stage of laser recording, these layers are preferably provided so as to allow delamination at the time when images, such as color a proofs, are transferred to printing paper. In the case of forming color filters, on the other hand, the delamination capability is not always required. When the transfer to another support, such as a glass plate, is desired, it is, however, preferable that the image-receiving layer and the cushion layer be provided so as to permit delamination. In order to make the delamination easy, it is appropriate that a release layer having a thickness of the order of 0.1-2 μm be provided between the cushion layer and the image-receiving layer. When the release layer is too thick, the cushion layer becomes difficult to exert its effect. So it is required to control the thickness of the release layer by properly selecting a material used therein.

Examples of binder usable for the release layer include thermosetting resins having Tg of 65° C. or higher, such as polyolefin, polyester, polyvinyl acetal, polyvinyl formal, polyparabanic acid, polymethacrylic acid, polycarbonate, ethyl cellulose, nitrocellulose, methyl cellulose, carboxymethyl cellulose, hydroxypropyl cellulose, polyvinyl alcohol, polyvinyl chloride, urethane resin, fluorine-contained resin, styrene polymers such as polystyrene and acrylonitrile-styrene copolymer, and cross-linking products of these resins, polyamide, polyimide, polyetherimide, polysulfone, polyether sulfone and aramide, and cured matters of the resins as recited above. As examples of a curing agent usable therein, mention may be made of general curing agents, such as isocyanate and melamine.

When the binder for the release layer is selected so as to suit for the foregoing physical properties, polycarbonate, acetals and ethyl cellulose are preferred from the viewpoint of keeping quality. In addition to selection of such resins, the use of acrylic resin for the image-receiving layer is advantageous in particular. This is because the use of those resins in combination can ensure satisfactory delamination upon re-transfer of images after laser thermal transfer.

In another way, it is possible to use as the release layer a layer capable of extremely lowering its adherence to the image-receiving layer when it undergoes cooling. Specifically, such a layer contains as a main component a heat-fusible compound, such as wax, or a thermoplastic resin.

As examples of a heat-fusible compound, mention may be made of the materials as disclosed in JP-A-63-103886. In particular, microcrystalline wax, paraffin wax and carnauba wax are preferred over the others. As to the thermoplastic resin, ethylene copolymers such as ethylene-vinyl acetate copolymer, and cellulose resins are preferably used.

To such a release layer, a higher fatty acid, a higher alcohol, a higher fatty acid ester, an amide and a higher amine can be added as additives, if desired.

In still another way, the release layer can be designed so that the layer itself causes aggregative destruction through fusion or softening upon heating and thereby gets releasability. It is advantageous to incorporate a supercooling substance in such a release layer.

Examples of such a supercooling substance include poly-ε-caprolactone, polyoxyethylene, benzotriazole, tribenzylamine and vanillin.

Further, the release layer can be designed differently from the above. Specifically, the release layer can contain a compound capable of lowering its adherence to the image-receiving layer. Examples of such a compound include silicone polymers such as silicone oil, fluorine-contained resins such as Teflon and fluorine-contained acrylic resins, polysiloxane resins, acetal resins such as polyvinyl butyral, polyvinyl acetal and polyvinyl formal, solid wax such as polyethylene wax or amide wax, and surfactants of fluorine-containing type and phosphate type.

Such a release layer can be formed on a cushion layer by applying a solution or latex of substances as recited above in accordance with a coating method using a blade coater, a roll coater, a bar coater, a curtain coater or a gravure coater, or a lamination method using hot melt extrusion. Also, it can be formed in the other way. Specifically, a solution or latex of substances as recited above is coated on a temporary base in accordance with the method as recited above, the coating formed is applied to the cushion layer, and then the temporary base is peeled away.

The image-receiving sheet to be combined with the thermal transfer sheet may have a structure that the image-receiving layer can function as a cushion layer also. In this case, the image-receiving sheet may comprise a combination of a support and an image-receiving cushion layer or a combination of a support, a subbing layer and an image-receiving cushion layer. Herein also, it is preferable to provide the image-receiving cushion layer so as to permit delamination from the viewpoint of re-transfer to printing paper. And the images re-transferred to printing paper come to have high glossiness.

Additionally, the suitable thickness of image-receiving cushion layer is from 5 to 100 μm, preferably from 10 to 40 μm.

From the viewpoint of improvement in running properties of the image-receiving sheet, it is advantageous that the image-receiving sheet has a backing layer on the back of its support, which is opposite to the side of the image-receiving layer. The addition of an antistatic agent, such as a surfactant or particulate tin oxide, and a matting agent, such as silicon oxide or PMMA particles, to the backing layer can ensure smooth travelling of the image-receiving sheet inside the recording system.

In addition to the backing layer, those additives can also be added to the image-receiving layer and other layers, if needed. The kinds of additives needed cannot be generalized, but depend on the intended purposes. As a guide, however, a matting agent having an average particle size of 0.5 to 10 μm can be added in a proportion of the order of 0.5-80% to the layer. As to the antistatic agent, compounds selected appropriately from various surfactants or conductive agents can be added in such an amount that a surface resistance of 10¹² Ω or below, preferably 10⁹ Ω or below, as measured under a condition of 23° C.-50% RH is imparted to the layer.

In the case of forming a color filter on the image-receiving sheet, it is appropriate that those additives be added in amounts capable of ensuring transparency of the color filter.

Examples of a binder usable in the backing layer include polymers for general purpose use, such as gelatin, polyvinyl alcohol, methyl cellulose, nitrocellulose, acetyl cellulose, aromatic polyamide resin, silicone resin, epoxy resin, alkyd resin, phenol resin, melamine resin, fluorine-contained resin, polyimide resin, urethane resin, acrylic resin, urethane-modified silicone resin, polyethylene resin, polypropylene resin, polyester resin, Teflon resin, polyvinyl butyral resin, vinyl chloride resin, polyvinyl acetate, polycarbonate, organoboron compounds, aromatic esters, fluorinated polyurethane and polyether sulfone.

In preventing the matting agent added to the backing layer from coming off and enhancing scratch resistance of the backing layer, it is effective to use a cross-linkable water-soluble binder as the binder of the backing layer and subject the binder to cross-linking reaction. Such a cross-linked binder can have a great effect upon inhibition of blocking upon storage, too.

As to a means for cross-linking, there is no particular restriction, but heat, actinic rays and pressure can be adopted alone or in combination depending on the characteristics of a cross-linking agent used. In some cases, an adhesive layer may be provided on the backing layer side of the support in order to secure adherence to the support.

The matting agent added suitably to the backing layer is organic or inorganic fine particles. Examples of an organic matting agent include fine particles of a polymer of radical polymerization type, such as polymethyl methacrylate (PMMA), polystyrene, polyethylene or polypropylene, and fine particles of a condensation polymer, such as polyester or polycarbonate.

The suitable coverage of the backing layer is of the order of 0.5-5 g/m². When the coverage is below 0.5 g/m², the coating formed is unstable and the matting agent added thereto tends to cause a coming-off trouble. When the coverage is increased much beyond the value of 5 g/m², the particle size suitable for a matting agent added to such a thick layer is also increased; as a result, the particles of the matting agent are embossed on the image-receiving layer surface during the storage, and thereby the recorded images tend to suffer from clear spots and unevenness, particularly in the thermal transfer where a thin image-forming layer is transferred.

It is appropriate that the number average particle size of the matting agent be 2.5 to 20 μm greater than the thickness of the binder-alone part of the backing layer. The matting agent is required to comprise particles having sizes of no smaller than 8 μm in a proportion capable of providing a coverage of at least 5 mg/m², preferably from 6 to 500 mg/m². By adding such a matting agent, the foreign matter trouble can be reduced in particular. Moreover, the use of a matting agent having such a narrow particle size distribution that the value σ/rn (variation coefficient of particle size distribution) obtained by dividing the standard deviation of particle size distribution by a number average particle size is not greater than 0.3 can reduce the defects caused by particles having exceptionally large sizes, and further can achieve the intended properties in a smaller amount. And greater effects can be obtained by controlling such a variation coefficient to 0.15 or below.

Addition of an antistatic agent to the backing layer is beneficial in preventing a foreign matter from adhering to the backing layer through electrification by friction against transfer rolls. As the antistatic agent can be used various kinds of compounds including cationic surfactants, anionic surfactants, nonionic surfactants, high molecular antistatic agents, conductive fine particles, and the compounds described in 11290 Kagaku Shohin (which may be translated “11290 Chemical Products”), pp. 875-876, Kagaku Kogyo Nipposha.

Of the substances recited above as antistatic agents usable for the backing layer, carbon black, metal oxides, such as zinc oxide, titanium dioxide and tin oxide, and conductive fine particles, such as organic semiconductors, are preferred over the others. In particular, conductive fine particles are used to advantage because they hardly cause separation from the backing layer and can produce consistent antistatic effect without influenced by environments.

To the backing layer, various activators, silicone oils and fluorine-contained resins can be further added for the purpose of imparting thereto coatability and mold releasing properties.

When the softening points of the cushion layer and the image-receiving layer are 70° C. or below as measured by thermomechanical analysis (TMA), it is particularly effective to form the backing layer.

The TMA softening point can be determined by raising the temperature of a subject at a constant temperature-rise speed while applying a constant load to the subject, and observing the phase of the subject. In the invention, the TMA softening point is defined as the temperature at which the phase of a subject starts to change. The measurement of softening points by TMA can be performed with a commercial apparatus, such as Termoflex made by Rigaku Denki Co., Ltd.

The thermal transfer sheet and the image-receiving sheet can be utilized for image formation in the form of a laminate in which the image-forming layer of the thermal transfer sheet and the image-receiving sheet or the image-receiving layer thereof are in face-to-face contact.

The laminate of the thermal transfer and image-receiving sheets can be formed using various methods. For instance, the laminate can be formed with ease by superimposing the image-receiving sheet or the image-receiving layer thereof upon the image-forming layer of the thermal transfer sheet, and passing them between pressing and heating rollers. In this case, the suitable heating temperature is 160° C. or below, preferably 130° C. or below.

For forming the foregoing laminate, the vacuum contact method as described hereinbefore can also be adopted. Specifically, the vacuum contact method comprises winding an image-receiving sheet around a drum having holes for vacuum suction, and subsequently in vacuo bringing a thermal transfer sheet having a size a little greater than the size of the image-receiving sheet into close contact with the image-receiving sheet while uniformly pressing out air by means of squeeze rollers. In still another method, the image-receiving sheet is stuck upon a metallic drum mechanically while imposing tension thereon, and further thereon the thermal transfer sheet is stuck up mechanically while imposing tension thereon in a similar manner, thereby forming a laminate. Of these methods, the vacuum contact method is preferred over the others since it requires no temperature control of heating rollers and can ensure rapid and uniform lamination.

### EXAMPLE

The invention will now be illustrated in more detail by reference to the following examples. However, these examples are not to be construed as limiting the scope of the invention in any way. Additionally, all parts in the following examples are by weight unless otherwise indicated.

### Example 1

1. Preparation of Thermal Transfer Sheet:

1-1. Formation of Cushion Layer

Coating Composition for Formation of Cushion Layer:

| | | |
|---|---|---|
| Vinyl chloride-vinyl acetate copolymer | 25 | parts |
| (MPR-TSL, trade name, a product of Nisshin | | |
| Chemical Industry Co., Ltd.) | | |
| Plasticizer | 12 | parts |
| (hexafunctional acrylate monomer having | | |
| molecular weight of 1947, DPCA-120, trade | | |
| name, a product of Nippon Kayaku Co., Ltd.) | | |
| Surfactant | 0.4 | parts |
| (Megafac F-177, trade name, a product of | | |
| Dai-Nippon Ink & Chemicals Inc.) | | |
| Methyl ethyl ketone | 75 | parts |

The above-described composition was coated on a 100 μm-thick biaxially stretched PET base in an amount to form a layer having a dry thickness of about 20 μm.

1-2. Formation of Photothermal Converting Layer

(1) Preparation of Coating Composition for Light-to-Heat Converting Layer

The following ingredients were mixed with stirring by means of a stirrer to prepare a coating composition for forming a photothermal converting layer.

Coating Composition:

| | | |
|---|---|---|
| Infrared absorbing dye | 10 | parts |
| (NK-2014, trade name, a product of Nippon | | |
| Kanko Shikiso Co., Ltd.) | | |
| Binder | 200 | parts |
| (Rika Coat SN-20, a product of Shin-Nippon | | |
| Rika Co., Ltd.) | | |
| N-Methyl-2-Pyrrolidone | 2000 | parts |
| Surfactant | 1 | parts |
| (Megafac F-177, trade name, a product of | | |
| Dai-Nippon Ink & Chemicals Inc.) | | |

(2) Formation of Photothermal Converting Layer on Substrate Surface

On the surface of the aforementioned coating for cushion layer, the coating composition described above was coated with a whirler, and then dried for 2 minutes in a 100° C. oven to form a photothermal converting layer on the substrate. The photothermal converting layer formed had its absorption maximum at about 830 nm in the wavelength region of 700 to 1,000 nm, and the absorbance at this wavelength (optical density abbreviated as “OD”) was 1.0 as measured with a Macbeth densitometer. The cross-section of the coating formed as a photothermal converting layer was observed under a scanning electron microscope, and thereby the thickness of the coating was found to be 0.3 μm on the average.

1-3. Formation of Image-Forming Layer

(3) Preparation of Coating Composition for Image-Forming Layer

The following ingredients were dispersed for 2 hours with a paint shaker (made by Toyo Seiki Co., Ltd.), and then the glass beads were removed therefrom. Thus, a mother dispersion of red pigment was prepared.

Composition of Mother Dispersion of Red Pigment:

| | | |
|---|---|---|
| 20 weight % n-Propyl alcohol solution of | 12.6 | parts |
| polyvinyl butyral | | |
| (Vicat softening point of 57° C., Denka Butyral | | |
| #2000-L, trade name, a product of Electro | | |
| Chemical Industry Co., Ltd.) | | |
| Coloring material (Irgazine Red BPT) | 24 | parts |
| Dispersing aid | 0.8 | parts |
| (Solsperse S-20000, trade name, a product | | |
| of ICI Co., Ltd.) | | |
| n-Propyl alcohol | 110 | parts |
| Glass beads | 100 | parts |

The following ingredients were mixed with stirring by means of a stirrer to prepare a coating composition for forming an red image-forming layer.

Coating Composition:

| | | |
|---|---|---|
| Mother dispersion of red pigment | 20 | parts |
| mentioned above | | |
| n-Propyl alcohol | 60 | parts |
| Surfactant | 0.05 | parts |
| (Megafac F-177, trade name, a | | |
| product of Dai-Nippon Ink & | | |
| Chemicals Inc.) | | |

In the same manner as described above, green and blue image-forming coating compositions were prepared, except that copper phthalocyanine (green) pigment and Sudan blue pigment were used respectively in place of Irgazine Red BPT.

(4) Formation of Red Image-Forming Layer on Surface of Photothermal Converting Layer

The foregoing coating composition was coated on the surface of the photothermal converting layer formed above, and then dried for 2 minutes in a 100° C. oven, thereby forming on the photothermal converting layer a red image-forming layer (constituted of 64.2 weight % and 33.7 weight % of polyvinyl butyral) . The absorbance (optical density abbreviated as “OD”) of the image-forming layer obtained was 0.7 as measured with a Macbeth densitometer TD504 (B). The coating thickness was 0.4 μm on the average as measured in the same manner as described above. Thus, a thermal transfer sheet having on the base the cushion layer, the photothermal converting layer and the red image-forming layer, which were arranged in the order of mention, was prepared. Similarly to the above, transfer sheets having the green image-forming layer and the blue image-forming layer respectively were prepared.

(5) Preparation of Coating Composition for Forming Black Image-Forming Layer

The following ingredients were placed in the mill of a kneader, and subjected to pretreatment for dispersion while adding a small amount of solvent and imposing shearing stress thereon. To the dispersion obtained, the solvent was further added so that the following composition was prepared finally, and subjected to 2-hour dispersion with a sand mill. Thus, a mother dispersion of pigment was obtained.

[Composition of Mother Dispersion of Black Pigment]

| Composition (1) | | |
|---|---|---|
| Polyvinyl butyral | 12.6 | parts |
| (Esleck B BL-SH, trade name, a product of | | |
| Sekisui Chemical Co., Ltd.) | | |
| Pigment Black 7 (Carbon black C.I. No. | 4.5 | parts |
| 77266) | | |
| (Mitsubishi Carbon Black MA100 having PVC | | |
| blackness of 1, a product of Mitsubishi | | |
| Chemical Corporation) | | |
| Dispersing aid | 0.8 | parts |
| (Solsperse S-20000, trade name, a product of | | |
| ICI Co., Ltd.) | | |
| n-Propyl alcohol | 79.4 | parts |
| Composition (2) | | |
| Polyvinyl butyral | 12.6 | parts |
| (Esleck B BL-SH, trade name, a product of | | |
| Sekisui Chemical Co., Ltd.) | | |
| Pigment Black 7 (Carbon black C.I. No. | 10.5 | parts |
| 77266) | | |
| (Mitsubishi Carbon Black #5 having PVC | | |
| blackness of 10, a product of Mitsubishi | | |
| Chemical Corporation) | | |
| Dispersing aid | 0.8 | parts |
| (Solsperse S-20000, trade name, a product | | |
| of ICI Co., Ltd.) | | |
| n-Propyl alcohol | 79.4 | parts |

Then, the following ingredients were mixed with stirring by means of a stirrer to prepare a coating composition for black image-forming layer.

[Coating Composition for Black Image-forming Layer]

| | | |
|---|---|---|
| The foregoing mother dispersion of black | 185.7 | parts |
| pigments (Composition (1)/Composition (2) | | |
| ratio = 70:30 by parts) | | |
| Polyvinyl butyral | 11.9 | parts |
| (Esleck B BL-SH, trade name, a product of | | |
| Sekisui Chemical Co., Ltd.) | | |
| Wax compounds | | |
| Stearic acid amide (Neutron 2, produced | 1.7 | parts |
| by Nippon Seika Co., Ltd.) | | |
| Behenic acid amide (Diamid BM, produced | 1.7 | parts |
| by Nippon Kasei Co., Ltd.) | | |
| Lauric acid amide (Diamid Y, produced | 1.7 | parts |
| by Nippon Kasei Co., Ltd.) | | |
| Palmitic acid amide (Diamid KP, produced | 1.7 | parts |
| by Nippon Kasei Co., Ltd.) | | |
| Erucic acid amide (Diamid L-200, produced | 1.7 | parts |
| by Nippon Kasei Co., Ltd.) | | |
| Oleic acid amide (Diamid O-200, produced | 1.7 | parts |
| by Nippon Kasei Co., Ltd.) | | |
| Rosin | 11.4 | parts |
| (KE-311, produced by Arakawa Kagaku Co., | | |
| Ltd., containing 80-97% of resin acids | | |
| constituted of 30-40% of abietic acid, | | |
| 10-20% of neoabietic acid, 14% of dihydro- | | |
| abietic acid and 14% of tetrahydroabietic acid) | | |
| Surfactant | 2.1 | parts |
| (Megafac F-176PF, solid content of 20%, | | |
| a product of Dai-Nippon Ink & Chemicals Inc.) | | |
| Inorganic pigment | 7.1 | parts |
| (MEK-ST, 30% methyl ethyl ketone solution, | | |
| produced by Nissan Chemical Industries, Ltd.) | | |
| n-Propyl alcohol | 1050 | parts |
| Methyl ethyl ketone | 295 | parts |

In the same manner as in formation of the thermal transfer sheet having the red image-forming layer, the foregoing coating composition for black image-forming layer was coated on the photothermal converting layer surface to prepare a thermal transfer sheet having a black image-forming layer.

2. Preparation of Image-Receiving Sheet:

A 200 μm-thick polyether sulfone film, FS-1300 (trade name, a product of Sumitomo Bakelite Co., Ltd.) was used as support for an image-receiving sheet, and thereon the following composition was coated in a layer having a thickness of 1 μm.

| | | |
|---|---|---|
| Polyvinyl butyral | 16 | parts |
| (Denka Butyral #2000-L, trade name, | | |
| a product of Electro Chemical Industry Co., Ltd.) | | |
| Surfactant | 0.05 | parts |
| (Megafac F-177, trade name, a product of | | |
| Dai-Nippon Ink & Chemicals Inc.) | | |
| n-Propyl alcohol | 100 | parts |

3. Formation of Images:

The image-receiving sheet prepared above (measuring 25 cm×35 cm in size) was wound around a rotating drum having a diameter of 25 cm and provided with 12-mm-dia suction holes for vacuum adsorption (in a density of one hole per area of 3 cm×3 cm), and made to adsorb thereto. Then, the thermal transfer sheet measuring 30 cm×40 cm in size was superposed on the image-receiving sheet so as to equally extend off the image-receiving sheet, and brought into a close contact with the image-receiving sheet while squeezing air by means of squeeze rollers and sucking air into the suction holes, thereby preparing a laminate of the image-receiving sheet and the thermal transfer sheet. Therein, the degree of decompression relative to 1 atmospheric pressure in a state that the suction holes were blocked was −150 mmHg (≈81.13 kPa).

Then, the drum was made to rotate and laser image recording was performed on the laminate wound around the drum. Therein, semiconductor laser beams having a wavelength of 830 nm was gathered on the laminate surface from the outside of the drum so as to form a spot measuring 7 μm in size on the photothermal converting layer surface, and at the same time moved (sub-scanned) in the direction perpendicular to the rotating direction of the rotating drum (main scan direction) . The laser recording was carried out by imagewise irradiation with laser light via images corresponding to the color filter images shown in FIG. 3 from the side of the thermal transfer sheet. The laser irradiation conditions were as follows:

Laser power: 110 mW

Main-scan speed: 4 m/sec

Sub-scan pitch (sub-scan quantity per rotation): 6.35 μm

Temperature and humidity: 25° C. and 50% RH

After the laser recording, the laminate was demounted from the drum, and the image-receiving sheet was stripped off from the thermal transfer sheet with the hands. As a result, it was confirmed that only the laser-irradiated areas of the image-forming layer were transferred from the transfer sheet to the image-receiving sheet.

### Comparative Example

Images were formed on an image-receiving sheet in the same manner as in Example 1, except that the support of the image-receiving sheet was replaced by a PET film having the same thickness.

4. Method of Evaluating Image Quality:

The images obtained were allowed to stand for 1 hour at 250°C., and examined for dimensional change, adherence to the support, shape of transfer images, sensitivity and position accuracy of pixels. The evaluation criteria adopted were as follows.

Dimensional Change of Images

A: Change of 20 μm or below relative to the length of 500 mm

B: Change greater than 20 μm but no greater than 100 μm relative to the length of 500 mm

C: Change greater than 100 μm relative to the length of 500 mm

Adherence to Support

A: Tight adhesion to support (visual evaluation)

B: So-so adhesion to support but low scratch resistance

C: No adhesion to support

Shape of Transfer Images

A: Retention of original shape (visual evaluation)

B: Appearance of distortion in edge areas

C: Occurrence of total deformation

Sensitivity

A: Sufficient from the practical point of view

B: Somewhat inferior

C: impractical

Position Accuracy of Pixels

A: Deviation of 20 μm or below from the position at which pixels are essentially located

B: Deviation greater than 20 μm but no greater than 100 μm from the position at which pixels are essentially located

C: Deviation greater than 100 μm from the position at which pixels are essentially located

TABLE 1

| Evaluation Item | Example 1 | Comparative Example |
|---|---|---|
| Dimensional change | A | B or C |
| of images | | |
| Adherence to support | A | B or C |
| Shape of transfer | A | B or C |
| images | | |
| Sensitivity | A | B or C |
| Position accuracy of | A | B or C |
| pixels | | |

As can be seen from Table 1, the images formed according to the invention retained their quality at the initial level even after they were situated under the foregoing condition, and they produced satisfactory results. On the other hand, the images formed in Comparative Example were inferior in every item to the images formed in Example.

In accordance with the invention, contract proofs as an alternative to proofs or color arts can be provided with a response to the film-less CTP age. These contract proofs can reproduce colors matching up with prints and color arts for approval of customers. As it is possible to use the same coloring materials of pigment type as used in printing ink and transfer to printing paper, the invention can provide a DDCP system causing no moire. Further, the invention can provide a large-sized (A2/B2) digital direct color proof system highly close to prints since the invention enables transfer to printing paper and uses the same coloring materials of pigment type as used in printing ink. Furthermore, by the use of the image-forming materials as described above according to the invention, color filters usable in various display devices can be formed on flexible films. The invention is a system utilizing a laser thin-film thermal transfer method and pigment-type coloring materials, performing real-dot recording and enabling transfer to printing paper. Moreover, the invention can provide a multicolored image-forming method which enables formation of images of good qualities and consistent transfer densities on image-receiving sheets even when high-energy laser recording is carried out using laser light composed of a two-dimensional array of multiple beams under different temperature-humidity conditions, and further can provide a color filter-forming method using the foregoing multicolored image-forming method.

This application is based on Japanese Patent application JP 2001-018767, filed Jan. 26, 2001, the entire content of which is hereby incorporated by reference, the same as if set forth at length.

What is claimed is:

1. An image-forming material comprising:
an image-receiving sheet; and
a thermal transfer sheet comprising a first support, a photothermal converting layer and an image-forming layer, wherein the image-receiving sheet or each of the image-receiving sheet and the first support comprises a polyether sulfone layer comprising polyether sulfone.

2. The image-forming material according to claim 1, wherein the polyether sulfone has a glass transition temperature of from 200° C. to 250° C.

3. The image-forming material according to claim 1, wherein the polyether sulfone has a coefficient of linear expansion (ASTM D-696) of at most 10⁻³° C.⁻¹.

4. The image-forming material according to claim 1, which further comprises a cushion layer, wherein the first support, the cushion layer and the photothermal converting layer are located in this order.

5. The image-forming material according to claim 1, wherein the image-receiving sheet comprises an image-receiving layer and a second support, the second support comprising polyether sulfone.

6. The image-forming material according to claim 1, wherein the first support undergoes discharge treatment.

7. The image-forming material according to claim 5, wherein the second support undergoes discharge treatment.

8. The image-forming material according to claim 1, wherein the photothermal converting layer has a thickness of 0.5 μm or less.

9. The image-forming material according to claim 1, wherein the first support is a transparent synthetic resin material having a thickness of from 25 μm to 130 μm.

10. The image-forming material according to claim 1, wherein the photothermal converting layer comprises a binder, the binder having a thermal decomposition temperature of at least 400° C. and a glass transition temperature of from 200° C. to 400° C.

11. The image-forming material according to claim 1, wherein the image-forming layer comprises a binder, the binder being an amorphous organic high polymer having a softening point of from 40° C. to 150° C.

12. The image-forming material according to claim 5, wherein the image-receiving layer comprises a binder, the binder being a thermoplastic resin having a glass transition temperature of lower than 90° C.

13. A color filter-forming material comprising the image-forming material according to claim 1.

14. A method using the image-forming material according to claim 1 wherein the thermal transfer sheet is located on the image-receiving sheet, the method comprising radiating laser light from the side of the thermal transfer sheet through the thermal transfer sheet to form an image on the image-receiving sheet.

15. The method according to claim 14, wherein the laser light is light emitted from a semiconductor laser.

16. The method according to claim 14, wherein the photothermal converting layer is capable of absorbing light having a wavelength in the region of from 700 nm to 1,500 nm.

17. A method comprising conducting the method according to claim 14 to form a color filter.
